(19) United States
(12) Patent Application Publication
(10) Pub. No.: US 2018/0282148 A1
(43) Pub. Date: Oct. 4, 2018

(54) PRESSURE SENSOR, MANUFACTURING METHOD OF PRESSURE SENSOR, PRESSURE SENSOR MODULE, ELECTRONIC DEVICE, AND VEHICLE

(71) Applicant: SEIKO EPSON CORPORATION, Tokyo (JP)

(72) Inventor: Kazuya HAYASHI, Chino-shi (JP)

(73) Assignee: SEIKO EPSON CORPORATION, Tokyo (JP)

(21) Appl. No.: 15/919,764

(22) Filed: Mar. 13, 2018

(30) Foreign Application Priority Data
Mar. 28, 2017 (JP) 2017-063331

(51) Int. Cl. B81B 3/00; B81C 1/00; G01L 9/00

(52) U.S. Cl. CPC B81B 3/0072; B81C 1/00158; B81C 2201/0133; B81B 2201/0264; B81B 2203/0127; G01L 9/0055

(57) ABSTRACT

A pressure sensor includes a substrate having a diaphragm bent and deformed by pressure reception, a side wall portion disposed on one surface side of the substrate and surrounding the diaphragm in plan view of the substrate, a sealing layer disposed to face the diaphragm with space interposed between the sealing layer and the diaphragm and sealing the space, and a frame shaped metal layer positioned between the side wall portion and the sealing layer. The sealing layer includes a first sealing layer having a through-hole facing the space, and a second sealing layer positioned on a side opposite to the space with respect to the first sealing layer and sealing the through-hole, and an inner peripheral end of the metal layer is positioned between the through-hole and an outer edge of the diaphragm in plan view of the substrate.

### BACKGROUND

### 1. Technical Field

The present invention relates to a pressure sensor, a manufacturing method of the pressure sensor, a pressure sensor module, an electronic device, and a vehicle.

### 2. Related Art

In the related art, as a pressure sensor, a configuration described in JP-A-2015-184100 is known. The pressure sensor of JP-A-2015-184100 includes a substrate having a diaphragm bent and deformed by pressure reception and a peripheral structured body disposed on the substrate, and a pressure reference chamber is formed between the substrate and the peripheral structured body in the pressure sensor. The peripheral structured body has a frame shaped wall portion surrounding the pressure reference chamber and a ceiling portion covering an opening of the wall portion. Furthermore, the ceiling portion includes a coating layer having a through-hole for release etching and a sealing layer stacked on the coating layer and sealing the through-hole.

In the pressure sensor having such a configuration, the sealing layer is made of a metal material (material having a large thermal expansion coefficient) such as Al, Ti or the like. For that reason, due to thermal expansion of the sealing layer, internal stress of the diaphragm greatly changes depending on the environmental temperature. With this, there is a concern that even when the same pressure is received, a measured value varies depending on the environmental temperature and pressure measurement accuracy is reduced.

### SUMMARY

An advantage of some aspects of the invention is to provide a pressure sensor capable of exhibiting excellent pressure measurement accuracy, a manufacturing method of the pressure sensor, a pressure sensor module, an electronic device, and a vehicle.

The advantage described above can be achieved by the following configurations.

A pressure sensor according to an aspect of the invention includes a substrate having a diaphragm bent and deformed by pressure reception, a side wall portion disposed on one surface side of the substrate and surrounding the diaphragm in plan view of the substrate, a sealing layer disposed to face the diaphragm with space interposed between the sealing layer and the diaphragm and sealing the space, and a frame shaped metal layer positioned between the side wall portion and the sealing layer, and the sealing layer includes a first sealing layer having a through-hole facing the space and a second sealing layer positioned on a side opposite to the space with respect to the first sealing layer and sealing the through-hole, and an inner peripheral end of the metal layer is positioned between the through-hole and an outer edge of the diaphragm in plan view of the substrate.

With this configuration, the pressure sensor becomes able to exhibit excellent pressure measurement accuracy.

In the pressure sensor according to the aspect of the invention, the through-hole preferably overlaps with a central portion of the diaphragm in plan view of the substrate.

With this configuration, sufficient space can be secured between the through-hole and the outer edge of the diaphragm and the inner peripheral end of the metal layer can be easily positioned between the through-hole and the outer edge of the diaphragm.

In the pressure sensor according to the aspect of the invention, the metal layer preferably includes a base portion having a portion positioned between the side wall portion and the sealing layer and a connection portion positioned between the base portion and the substrate and connected to the base portion.

With this configuration, it is possible to cause the metal layer to function as an etching stopper when a sacrificial layer filling space to the middle of manufacturing is removed. Therefore, a size and shape of space can be defined by the metal layer and it becomes easy to form space having a desired shape.

In the pressure sensor according to the aspect of the invention, the connection portion is preferably embedded in the side wall portion.

With this configuration, it is possible to effectively reduce a change in internal stress due to thermal expansion of the metal layer. Accordingly, the pressure sensor becomes able to suppress the change in internal stress applied to the diaphragm due to an environmental temperature and exhibit excellent pressure measurement accuracy.

In the pressure sensor according to the aspect of the invention, the metal layer preferably contains aluminum.

With this configuration, it is possible to easily form the metal layer.

In the pressure sensor according to the aspect of the invention, the sealing layer preferably includes a third sealing layer positioned on a side opposite to the space with respect to the second sealing layer.

With this configuration, it is possible to more reliably seal the space.

A manufacturing method of a pressure sensor according to an aspect of the invention includes preparing a substrate having a diaphragm forming region, disposing a sacrificial layer overlapping with the diaphragm forming region in plan view of the substrate and a side wall portion positioned around the sacrificial layer on one surface side of the substrate, disposing a metal layer facing the substrate with the sacrificial layer interposed between the metal layer and the substrate and having a first through-hole facing the sacrificial layer, removing the sacrificial layer using the first through-hole, disposing a first sealing layer having a second through-hole on a side opposite to the substrate with respect to the metal layer, removing a portion of the metal layer by using the second through-hole and forming the metal layer to have a frame shape so that an inner peripheral end of the metal layer is positioned between the second through-hole and the outer edge of the diaphragm forming region in plan view of the substrate, disposing a second sealing layer for sealing the second through-hole on a side opposite to the substrate with respect to the first sealing layer, and forming a diaphragm bent and deformed by pressure reception in the diaphragm forming region.

With this configuration, it is possible to obtain a pressure sensor capable of exhibiting excellent pressure measurement accuracy.

A pressure sensor module according to an aspect of the invention includes the pressure sensor according to the aspect of the invention and a package accommodating the pressure sensor.

With this configuration, it is possible to obtain the pressure sensor module capable of exhibiting the effect of the pressure sensor according to the aspect of the invention and having high reliability.

An electronic device according to an aspect of the invention includes the pressure sensor according to the aspect of the invention.

With this configuration, it is possible to obtain the electronic device capable of exhibiting the effect of the pressure sensor according to the aspect of the invention and having high reliability.

A vehicle according to an aspect of the invention includes the pressure sensor according to the aspect of the invention.

With this configuration, it is possible to obtain the vehicle capable of exhibiting the effect of the pressure sensor according to the aspect of the invention and having high reliability.

### BRIEF DESCRIPTION OF THE DRAWINGS

The invention will be described with reference to the accompanying drawings, wherein like numbers reference like elements.

FIG. 1 is a cross-sectional view illustrating a pressure sensor according to a first embodiment of the invention.

FIG. 2 is a plan view illustrating a sensor portion included in the pressure sensor illustrated in FIG. 1.

FIG. 3 is a view illustrating a bridge circuit including the sensor portion illustrated in FIG. 2.

FIG. 4 is an enlarged cross-sectional view illustrating a sealing layer included in the pressure sensor illustrated in FIG. 1.

FIG. 5 is a plan view illustrating the pressure sensor illustrated in FIG. 1.

FIG. 6 is a cross-sectional view illustrating a configuration in which a metal layer is removed from the pressure sensor illustrated in FIG. 1.

FIG. 7 is an enlarged cross-sectional view of the metal layer included in the pressure sensor illustrated in FIG. 1.

FIG. 8 is a flowchart illustrating a manufacturing process of the pressure sensor illustrated in FIG. 1.

FIG. 9 is a cross-sectional view for explaining a manufacturing method of the pressure sensor illustrated in FIG. 1.

FIG. 10 is another cross-sectional view for explaining the manufacturing method of the pressure sensor illustrated in FIG. 1.

FIG. 11 is another cross-sectional view for explaining the manufacturing method of the pressure sensor illustrated in FIG. 1.

FIG. 12 is another cross-sectional view for explaining the manufacturing method of the pressure sensor illustrated in FIG. 1.

FIG. 13 is another cross-sectional view for explaining the manufacturing method of the pressure sensor illustrated in FIG. 1.

FIG. 14 is another cross-sectional view for explaining the manufacturing method of the pressure sensor illustrated in FIG. 1.

FIG. 15 is another cross-sectional view for explaining the manufacturing method of the pressure sensor illustrated in FIG. 1.

FIG. 16 is another cross-sectional view for explaining the manufacturing method of the pressure sensor illustrated in FIG. 1.

FIG. 17 is another cross-sectional view for explaining the manufacturing method of the pressure sensor illustrated in FIG. 1.

FIG. 18 is another cross-sectional view for explaining the manufacturing method of the pressure sensor illustrated in FIG. 1.

FIG. 19 is another cross-sectional view for explaining the manufacturing method of the pressure sensor illustrated in FIG. 1.

FIG. 20 is a cross-sectional view illustrating a pressure sensor according to a second embodiment of the invention.

FIG. 21 is a cross-sectional view illustrating a pressure sensor according to a third embodiment of the invention.

FIG. 22 is a cross-sectional view for explaining a manufacturing method of the pressure sensor illustrated in FIG. 21.

FIG. 23 is another cross-sectional view for explaining the manufacturing method of the pressure sensor illustrated in FIG. 21.

FIG. 24 is another cross-sectional view for explaining the manufacturing method of the pressure sensor illustrated in FIG. 21.

FIG. 25 is another cross-sectional view for explaining the manufacturing method of the pressure sensor illustrated in FIG. 21.

FIG. 26 is a cross-sectional view illustrating a pressure sensor module according to a fourth embodiment of the invention.

FIG. 27 is a plan view of a support substrate included in the pressure sensor module illustrated in FIG. 26.

FIG. 28 is a perspective view illustrating an altimeter as an electronic device according to a fifth embodiment of the invention.

FIG. 29 is a front view illustrating a navigation system as an electronic device according to a sixth embodiment of the invention.

FIG. 30 is a perspective view illustrating an automobile as a vehicle according to a seventh embodiment of the invention.

### DESCRIPTION OF EXEMPLARY EMBODIMENTS

In the following, a pressure sensor, a manufacturing method of the pressure sensor, a pressure sensor module, an electronic device, and a vehicle according to the invention will be described in detail based on embodiments illustrated in the accompanying drawings.

### First Embodiment

First, a pressure sensor according to a first embodiment of the invention will be described.

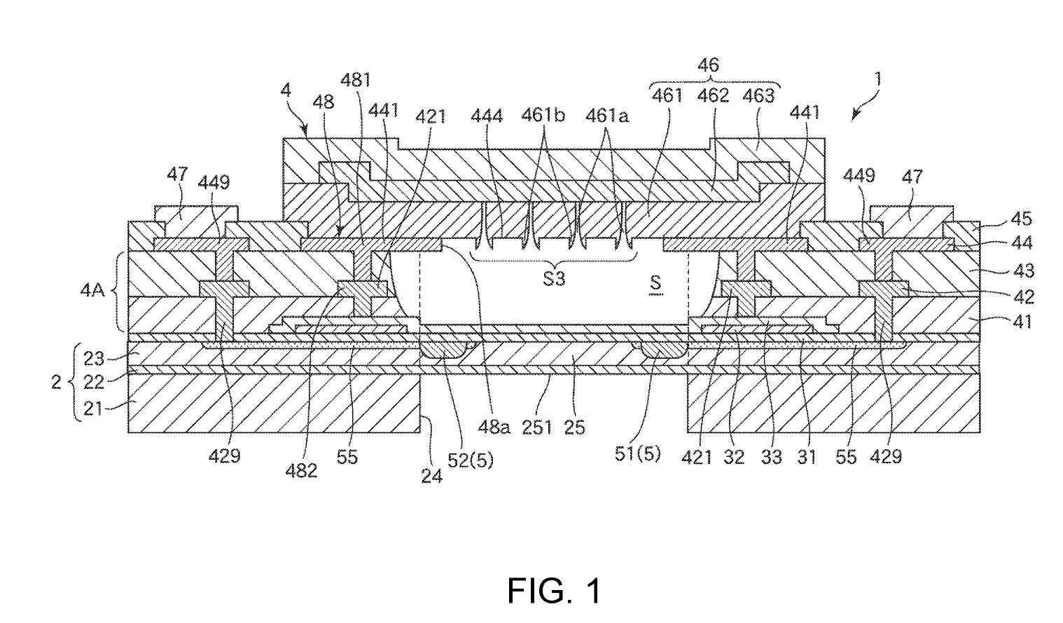

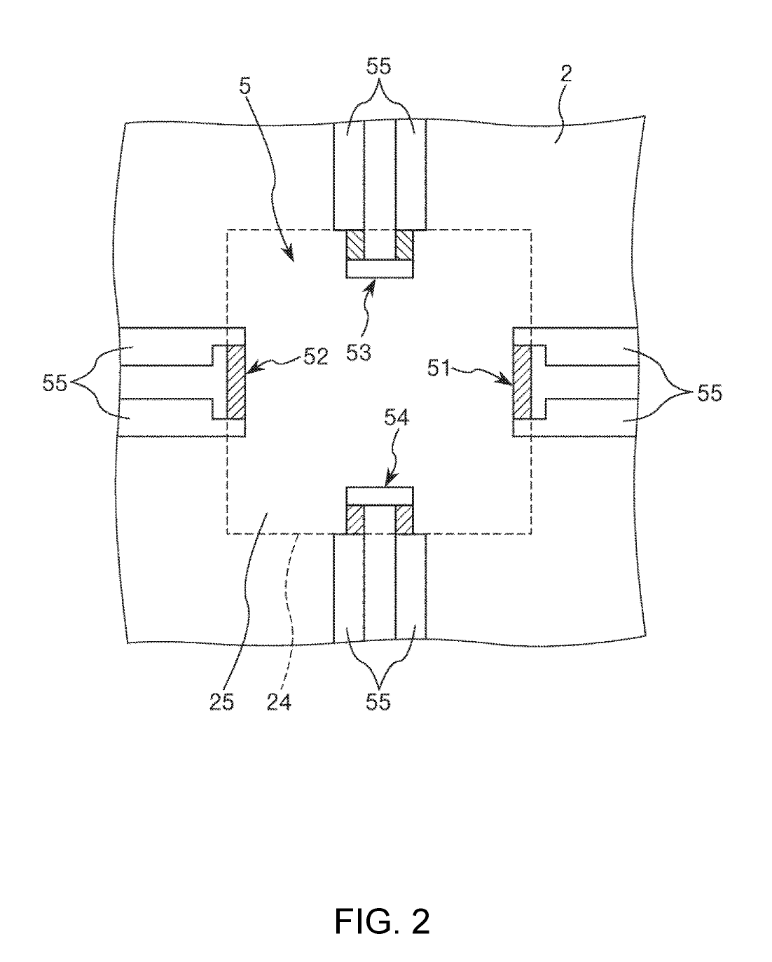

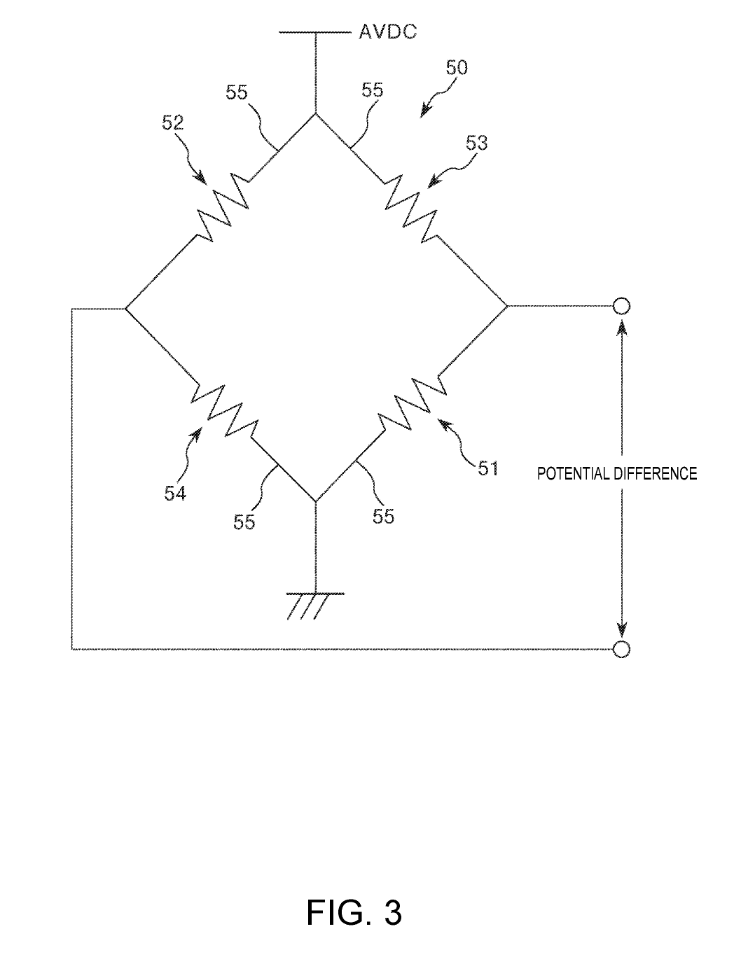

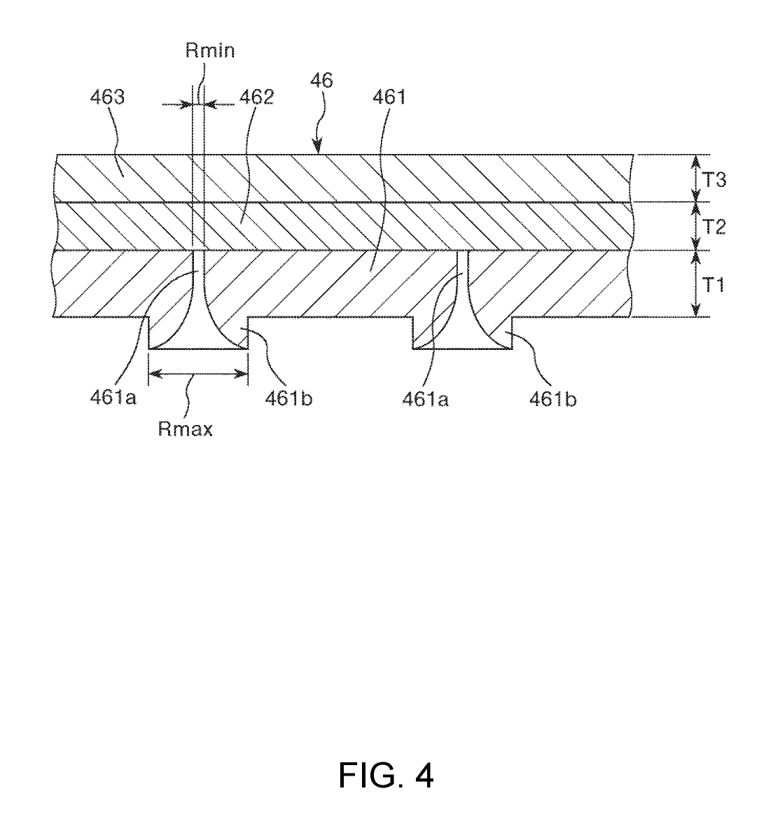

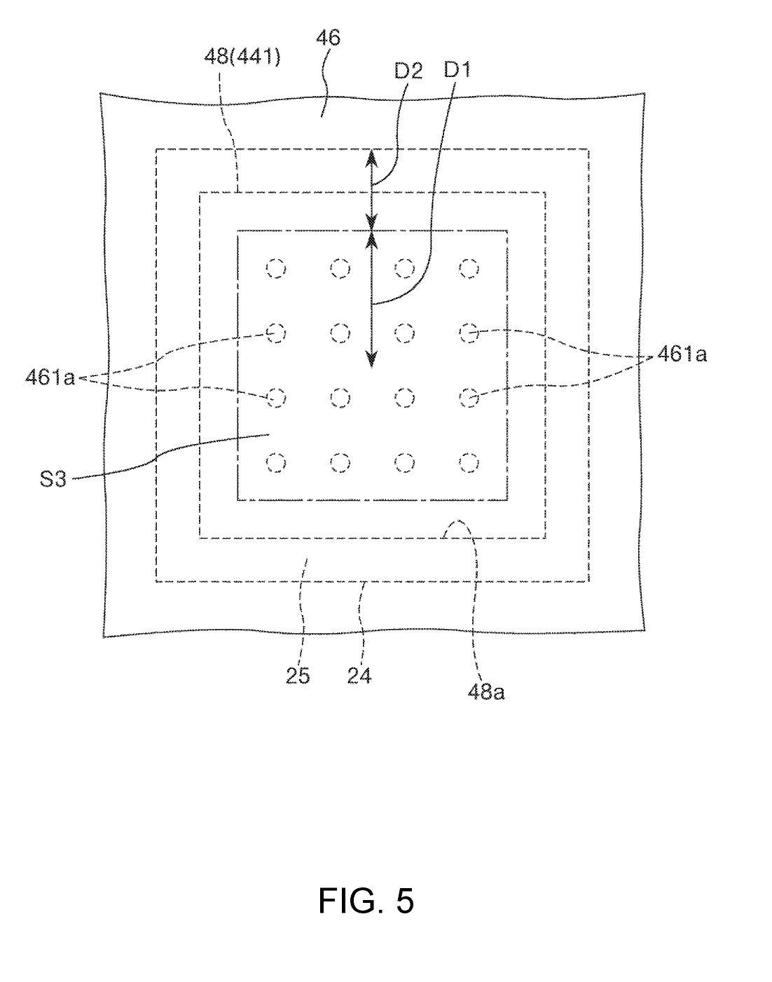

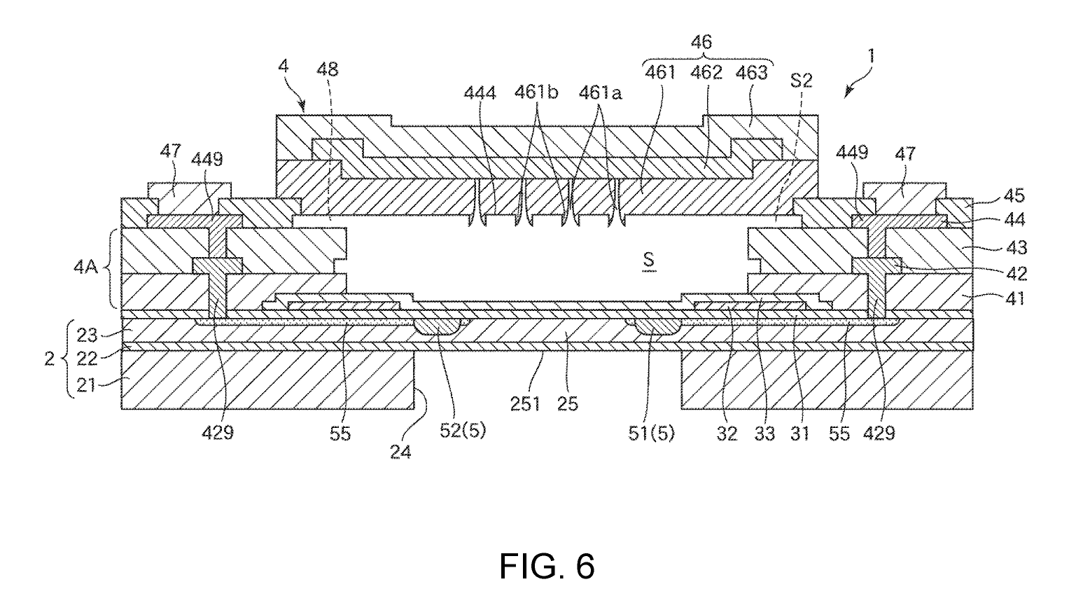

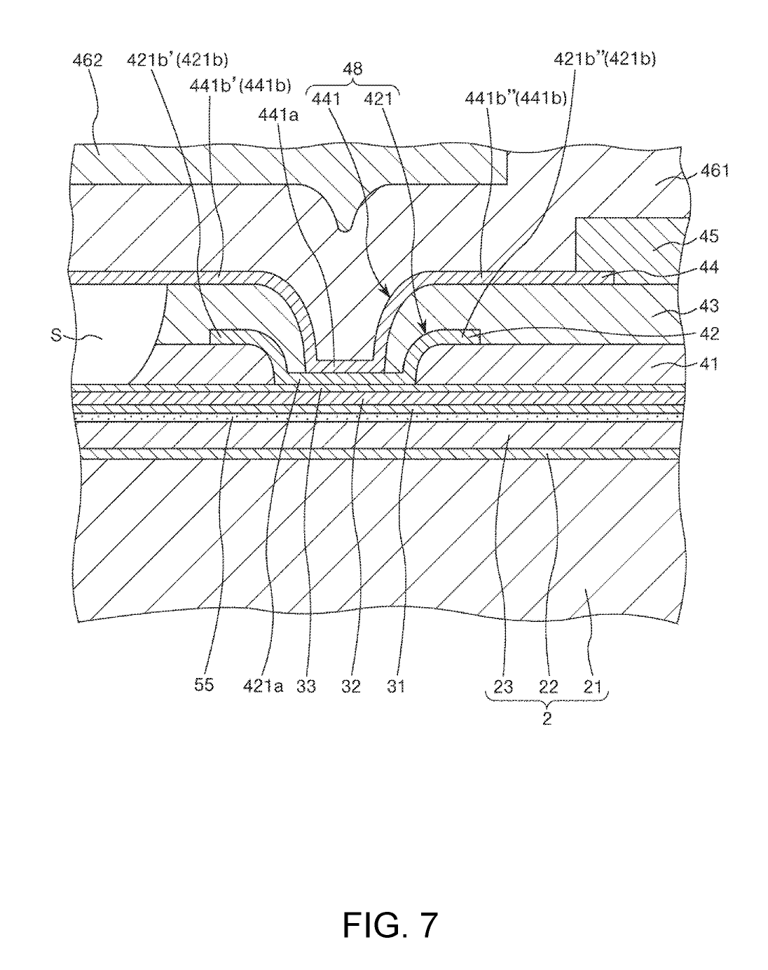

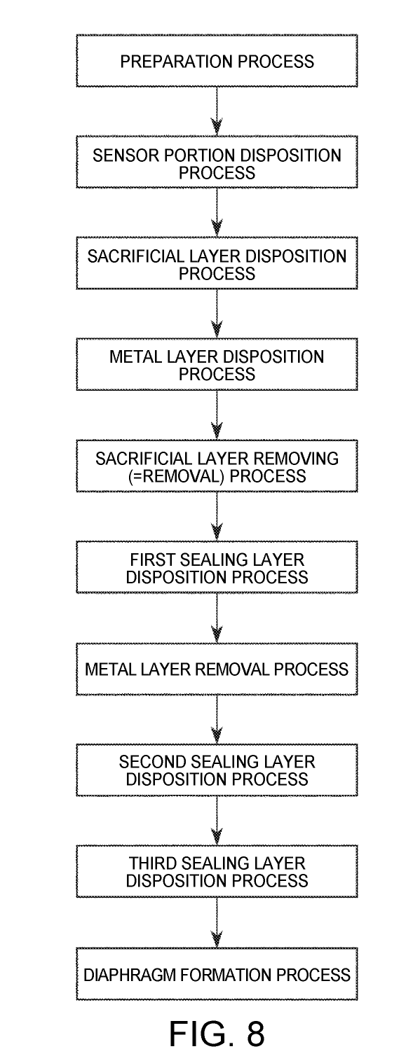

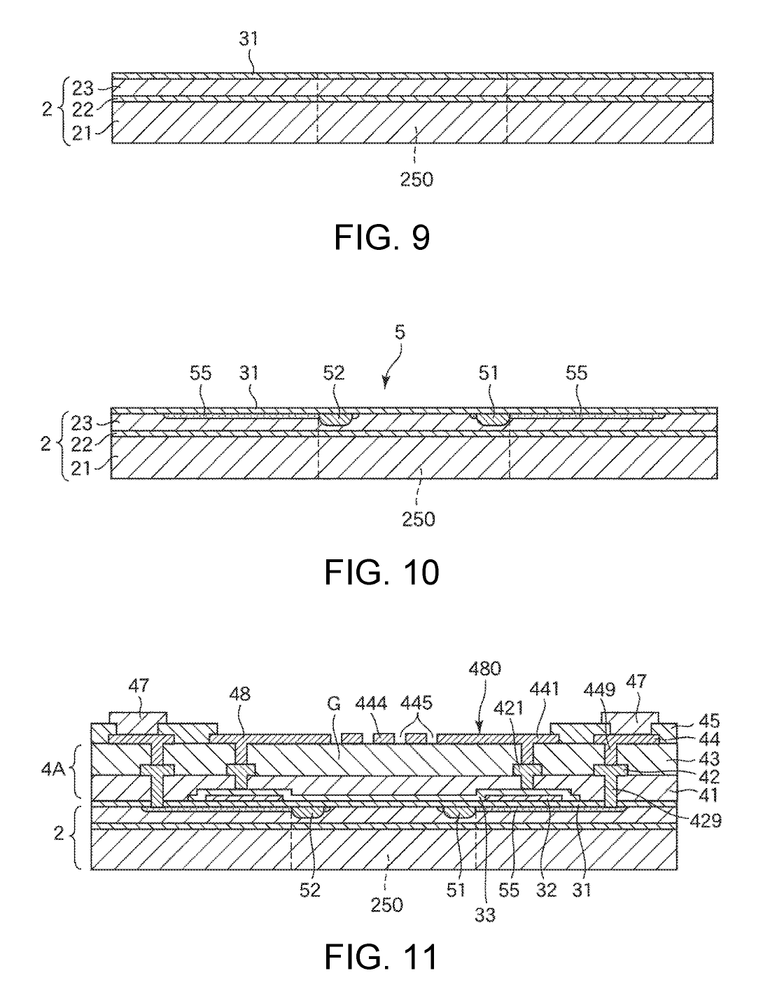

FIG. 1 is a cross-sectional view illustrating a pressure sensor according to a first embodiment of the invention. FIG. 2 is a plan view illustrating a sensor portion included in the pressure sensor illustrated in FIG. 1. FIG. 3 is a view illustrating a bridge circuit including the sensor portion illustrated in FIG. 2. FIG. 4 is an enlarged cross-sectional view illustrating a sealing layer included in the pressure sensor illustrated in FIG. 1. FIG. 5 is a plan view illustrating the pressure sensor illustrated in FIG. 1. FIG. 6 is a cross-sectional view illustrating a configuration in which a metal layer is removed from the pressure sensor illustrated in FIG. 1. FIG. 7 is an enlarged cross-sectional view of the metal layer included in the pressure sensor illustrated in FIG. 1. FIG. 8 is a flowchart illustrating a manufacturing process of the pressure sensor illustrated in FIG. 1. FIGS. 9 to 19 are cross-sectional views for explaining a manufacturing method of the pressure sensor illustrated in FIG. 1, respectively. In the following description, the upper side in FIGS. 1, 4, 6, 7, 9 to 19 is also referred to as “above” and the lower side is referred to as “below”. Also, plan view of the substrate, that is, plan view when seen from the vertical direction in FIG. 1 is simply referred to as “plan view”.

As illustrated in FIG. 1, a pressure sensor 1 includes a substrate 2 having a diaphragm 25 bent and deformed by pressure reception, a pressure reference chamber S (cavity portion) disposed on the upper surface side of the diaphragm 25, a peripheral structured body 4 forming the pressure reference chamber S together with the substrate 2, and a sensor portion 5 disposed on the diaphragm 25.

As illustrated in FIG. 1, the substrate 2 is configured with a SOI substrate including a first layer 21 made of silicon, a third layer 23 disposed above the first layer 21 and made of silicon, and a second layer 22 disposed between the first layer 21 and the third layer 23 and made of silicon oxide. That is, the substrate 2 contains silicon (Si). With this, the substrate 2 is easy to handle in manufacturing and can exhibit excellent processing dimensional accuracy. The substrate 2 is not limited to the SOI substrate, and for example, a single-layer silicon substrate can be used as the substrate 2. The substrate 2 may be a substrate (semiconductor substrate) made of a semiconductor material other than silicon, for example, germanium, gallium arsenide, gallium arsenide phosphorus, gallium nitride, silicon carbide, or the like.

As illustrated in FIG. 1, the substrate 2 is provided with the diaphragm 25 which is thinner than a surrounding portion and which is bent and deformed by pressure reception. A recess portion 24 that has a bottom and opens downward is formed on the substrate 2, and a portion where the substrate 2 is thinned by the recess portion 24 is the diaphragm 25. A lower surface of the diaphragm 25 is a pressure reception surface 251 that receives pressure. In the first embodiment, the diaphragm 25 has a substantially square shape as a shape in plan view, but the shape in plan view of the diaphragm 25 is not particularly limited, and may include, for example, a quadrangle other than a square, a polygon other than a quadrangle, a circle, an ellipse, an irregular shape, or the like. In the case of a polygon, each corner portion may be chamfered.

Here, in the first embodiment, the recess portion 24 is formed by dry etching using a silicon deep etching apparatus. Specifically, the recess portion 24 is formed by digging the first layer 21 by repeating processes such as isotropic etching, film-forming of protective film, and anisotropic etching from the lower surface side of the substrate 2. When the processes are repeated and etching reaches the second layer 22, the second layer 22 serves as an etching stopper and the etching is ended, and the recess portion 24 is obtained. According to such a forming method, an inner wall side surface of the recess portion 24 is substantially perpendicular to the main surface of the substrate 2 and thus, an opening area of the recess portion 24 can be reduced. For that reason, it is possible to suppress reduction in mechanical strength of the substrate 2 and to suppress an increase in size of the pressure sensor 1.

However, a method of forming the recess portion 24 is not limited to the method described above, and the recess portion 24 may be formed by wet etching, for example. In the first embodiment, the second layer 22 is left on the lower surface side of the diaphragm 25, but the second layer 22 may be removed. That is, the diaphragm 25 may be formed of a single layer of the third layer 23. With this, the diaphragm 25 can be made thinner, and the diaphragm 25 which is more easily bent and deformed can be obtained. The recess portion 24 may be formed to the middle of the first layer 21.

Although a thickness of the diaphragm 25 is not particularly limited and varies depending on the size of the diaphragm 25 and the like, for example, in a case where a width of the diaphragm 25 is 100 μm or more and 300 μm or less, the thickness of the diaphragm 25 is preferably 1 μm or more and 10 μm or less, and more preferably 1 μm or more and 3 μm or less. By setting the thickness to such a value, it is possible to obtain the diaphragm 25 which is sufficiently thin and easily bent and deformed by pressure reception while maintaining sufficient mechanical strength.

The diaphragm 25 is provided with a sensor portion 5 capable of measuring pressure acting on the diaphragm 25. As illustrated in FIG. 2, the sensor portion 5 includes four piezoresistive elements 51, 52, 53, and 54 provided on the diaphragm 25. The piezoresistive elements 51, 52, 53, and 54 are electrically connected to each other via wirings 55 and constitute a bridge circuit 50 (wheatstone bridge circuit) illustrated in FIG. 3. A drive circuit that supplies (applies) a drive voltage AVDC is connected to the bridge circuit 50. Then, the bridge circuit 50 outputs a measurement signal (voltage) according to change in the resistance value of the piezoresistive elements 51, 52, 53, and 54 based on bending of the diaphragm 25. For that reason, it is possible to measure pressure received by the diaphragm 25 based on the output measurement signal.

In particular, the piezoresistive elements 51, 52, 53, and 54 are disposed on the outer edge portion of the diaphragm 25. When the diaphragm 25 bends and deforms by pressure reception, large stress is applied particularly to the outer edge portion of the diaphragm 25 and thus, the piezoresistive elements 51, 52, 53, and 54 are disposed in the outer edge portion so as to make it possible to increase the measurement signal described above, and sensitivity of pressure measurement is improved. Disposition of the piezoresistive elements 51, 52, 53, 54 is not particularly limited and, for example, the piezoresistive elements 51, 52, 53, and 54 may be disposed across the outer edge of the diaphragm 25 and otherwise, may be disposed in the central portion of the diaphragm 25.

The piezoresistive elements 51, 52, 53, and 54 are formed by, for example, doping (diffusing or injecting) impurities such as phosphorus and boron into the third layer 23 of the substrate 2. The wiring 55 is formed by, for example, doping (diffusing or injecting) impurities such as phosphorus, boron, or the like into the third layer 23 of the substrate 2 at higher concentration than that of the piezoresistive elements 51, 52, 53, and 54.

The configuration of the sensor portion 5 is not particularly limited as long as the sensor portion 5 can measure pressure received by the diaphragm 25. For example, a configuration in which at least one piezoresistive element not constituting the bridge circuit 50 is disposed in the diaphragm 25 may be adopted. As the sensor portion 5, in addition to a piezoresistive type sensor portion as in the first embodiment, a capacitance type sensor portion that measures pressure based on a change in electrostatic capacitance may be used.

As illustrated in FIG. 1, a first insulating film 31 composed of a silicon oxide film (SiO₂ film) is formed on the upper surface of the substrate 2. With such a first insulating film 31, it is possible to reduce an interface level of the piezoresistive elements 51, 52, 53, and 54 and suppress occurrence of noise.

A second insulating film 32 composed of a silicon nitride film (SiN film) is formed on the first insulating film 31. The second insulating film 32 has a frame shape surrounding the periphery of the diaphragm 25 so as not to overlap with the diaphragm 25. A conductive film 33 composed of polysilicon (p-Si) is formed on the first insulating film 31 and the second insulating film 32. By the second insulating film 32 and the conductive film 33, the sensor portion 5 can be protected from moisture, gas, and the like. In the first embodiment, the second insulating film 32 is disposed so as not to overlap with the diaphragm 25, and the conductive film 33 is disposed so as not to overlap with the diaphragm 25. This is because the conductive film 33 can be deposited to be thinner than that of the second insulating film 32 and a real thickness of the diaphragm 25 (thickness obtained by adding thicknesses of the first insulating film 31 and the conductive film 33 to thickness of the diaphragm 25) can be made thinner.

The conductive film 33 also functions as an etching stopper when a sacrificial layer G filling the pressure reference chamber S is removed by etching, as described in a manufacturing method described later. With this, the first insulating film 31 and the sensor portion 5 can be protected during manufacturing. For example, the conductive film 33 is set to a reference potential (ground) or a drive voltage of the sensor portion 5 is applied to the conductive film 33 so as to make it possible for the conductive film 33 to function as a shield layer for protecting the sensor portion 5 from external disturbance. For that reason, the sensor portion 5 is hardly affected by disturbance and the pressure measurement accuracy of the pressure sensor 1 can be further enhanced.

At least one of the first insulating film 31, the second insulating film 32, and the conductive film 33 may be omitted or may be made of a different material.

As illustrated in FIG. 1, the pressure reference chamber S is provided above the diaphragm 25. The pressure reference chamber S is formed by being surrounded by the substrate 2 and the peripheral structured body 4. The pressure reference chamber S is sealed space and pressure in the pressure reference chamber S is a reference value of the pressure measured by the pressure sensor 1. In particular, the pressure reference chamber S is preferably in a vacuum state (for example, 10 Pa or less). With this, the pressure sensor 1 can be used as an “absolute pressure sensor” for measuring pressure by using a vacuum as a reference and the pressure sensor 1 becomes a highly convenient pressure sensor 1. However, the pressure reference chamber S may not be in a vacuum state as long as the pressure reference chamber S is kept at a constant pressure.

The pressure reference chamber S has a tapered shape of which the cross-sectional area gradually increases from the substrate 2 side toward the sealing layer 46 side. That is, an area of the substrate 2 side is smaller than an area of the sealing layer 46 side. In the pressure reference chamber S, a change rate of the cross-sectional area of the tapered shape gradually decreases from the substrate 2 side toward the sealing layer 46 side. However, the shape of the pressure reference chamber S is not particularly limited, and the area of the pressure reference chamber S may be, for example, substantially constant from the substrate 2 side toward the sealing layer 46 side.

The peripheral structured body 4 allows the pressure reference chamber S to be formed between the peripheral structured body 4 and the substrate 2. The peripheral structured body 4 includes an interlayer insulating film 41 disposed on the substrate 2, a wiring layer 42 disposed on the interlayer insulating film 41, an interlayer insulating film 43 disposed on the wiring layer 42 and the interlayer insulating film 41, a wiring layer 44 disposed on the interlayer insulating film 43, a surface protective film 45 disposed on the wiring layer 44 and the interlayer insulating film 43, a sealing layer 46 disposed on the wiring layer 44 and the surface protective film 45, and a terminal 47 disposed on the surface protective film 45.

Each of the interlayer insulating films 41 and 43 has a frame shape and is disposed so as to surround the diaphragm 25 in plan view. A side wall portion 4A is configured with the interlayer insulating films 41 and 43. Space (that is, pressure reference chamber S) is formed inside the side wall portion 4A. A constituent material of the interlayer insulating films 41 and 43 is not particularly limited and, for example, silicon oxide (SiO₂) or the like can be used as the constituent material.

The wiring layer 42 has a frame shaped guard ring 421 disposed so as to surround the pressure reference chamber S and a wiring portion 429 connected to the wiring 55 of the sensor portion 5. The wiring layer 44 has a frame shaped guard ring 441 disposed so as to surround the pressure reference chamber S and a wiring portion 449 connected to the wiring 55. A metal layer 48 is configured with the guard rings 421 and 441. The metal layer 48 will be described later in detail. The constituent material of the wiring layers 42 and 44 is not particularly limited and includes, for example, various metals such as nickel, gold, platinum, silver, copper, manganese, aluminum, magnesium, and titanium, or alloy containing at least one of the metals and the like. Among the metals, aluminum is preferably used as a constituent material of the wiring layers 42 and 44, and aluminum is used in the first embodiment. With this, the wiring layers 42 and 44 can be easily formed in a semiconductor process such as a manufacturing method to be described later.

The surface protective film 45 has a function of protecting the peripheral structured body 4 from moisture, gas, dust, scratches, and the like. The surface protective film 45 is disposed on the interlayer insulating film 43 and the wiring layer 44. The constituent material of the surface protective film 45 is not particularly limited and, for example, silicon-based materials such as silicon oxide and silicon nitride, and various resin materials such as polyimide and epoxy resin can be used as the constituent material of the surface protective film 45.

On the surface protective film 45, a plurality of the terminals 47 electrically connected to the sensor portion 5 via wiring portions 429 and 449 are provided. The constituent material of the terminal 47 is not particularly limited and for example, the same material as the wiring layers 42 and 44 described above can be used as the constituent material of the terminal 47.

The sealing layer 46 is positioned on the ceiling of the pressure reference chamber S and is disposed to face the diaphragm 25 with the pressure reference chamber S, which is formed inside the side wall portion 4A, interposed between the sealing layer 46 and the diaphragm 25. The sealing layer 46 seals the pressure reference chamber S.

As illustrated in FIG. 1, the sealing layer 46 has a three-layer structure including a first sealing layer 461 of which the lower surface faces the pressure reference chamber S, a second sealing layer 462 stacked on the upper surface of the first sealing layer 461, and a third sealing layer 463 stacked on the upper surface of the second sealing layer 462. As such, the sealing layer 46 is formed in a stacked structure so as to make it possible to airtightly seal the pressure reference chamber S more reliably.

The first sealing layer 461 contains silicon (Si) and particularly in the first embodiment, is made of silicon (Si). The second sealing layer 462 contains silicon oxide (SiO₂), and particularly in the first embodiment, is made of silicon oxide (SiO₂). The third sealing layer 463 contains silicon (Si), and particularly in the first embodiment, is made of silicon (Si). As described in a manufacturing method to be described later, the first sealing layer 461, the second sealing layer 462, and the third sealing layer 463 can be formed by various film forming methods such as a sputtering method and a CVD method.

As such, each of the layers 461, 462, and 463 contains silicon (Si) so as to make it possible to easily form the sealing layer 46 by a semiconductor process as described in the manufacturing method to be described later. Furthermore, the second sealing layer 462 made of a different material (SiO₂) is sandwiched between the first sealing layer 461 and the third sealing layer 463 that are made of the same material (silicon) so as to make it possible to average the coefficient of thermal expansion of the sealing layer 46 in its thickness direction. For that reason, it is possible to suppress bending in the out-of-plane direction at the time of thermal expansion of the sealing layer 46.

In particular, contact between the sealing layer 46 and the diaphragm 25 can be suppressed by suppressing downward bending of the sealing layer 46. When the sealing layer 46 comes into contact with the diaphragm 25, bending deformation of the diaphragm 25 by pressure reception is hindered and pressure measurement accuracy is reduced. For that reason, as described above, bending in the out-of-plane direction at the time of thermal expansion of the sealing layer 46 is suppressed and contact between the sealing layer 46 and the diaphragm 25 is suppressed so as to allow the pressure sensor 1 to become a pressure sensor having excellent pressure measurement accuracy. As described above, the substrate 2 is made of the SOI substrate and thus, a difference in the coefficient of thermal expansion between the substrate 2 and the sealing layer 46 facing to each other with the pressure reference chamber S interposed therebetween can be reduced. For that reason, it is possible to suppress internal stress generated by thermal expansion to a small value. Furthermore, it is possible to suppress the change in the internal stress applied to the diaphragm 25 due to the environmental temperature. For that reason, for example, even when the same pressure is received, it is possible to effectively suppress reduction in measurement accuracy, that is, matters that the pressure to be measured varies depending on the environmental temperature.

Each of the first sealing layer 461 and the third sealing layer 463 may contain a material other than silicon (for example, material inevitably mixed in manufacturing), or may not contain silicon. Similarly, the second sealing layer 462 may contain a material other than silicon oxide (for example, a material inevitably mixed in manufacturing) or may not contain silicon oxide.

As illustrated in FIG. 1, a plurality of the through-holes 461a facing the pressure reference chamber S are formed in the first sealing layer 461. Each through-hole 461a is used as a hole for release etching for removing a coating layer 444 filling the pressure reference chamber S to the middle of manufacturing as will be described in a manufacturing method to be described later. As illustrated in FIG. 1, the plurality of through-holes 461a are positioned inside the frame shaped metal layer 48 in plan view of the substrate 2 and are disposed so as not to overlap the metal layer 48. The plurality of through-holes 461a are disposed so as to overlap the central portion of the diaphragm 25 without overlapping with an edge portion of the diaphragm 25, in plan view of the substrate 2. With this, excessive removal of the metal layer 48 via the through-hole 461a can be effectively suppressed, as will be described in the manufacturing method to be described later. Although a boundary between the central portion and the edge portion of the diaphragm 25 is not particularly limited, for example, as illustrated in FIG. 5, when the distance from the center of the diaphragm 25 to the boundary is set as D1 and the distance from the boundary to the outer edge of the diaphragm 25 is set as D2, the boundary can be set so as to satisfy the relationship of 0.5≤D1/D2≤2.

As such, the first sealing layer 461 has the plurality of through-holes 461a and thus, the first sealing layer 461 is easily deformed (stretched/contracted) in the plane direction. For that reason, for example, the first sealing layer 461 is deformed so as to make it possible to absorb and relax the internal stress of the pressure sensor 1. For that reason, the internal stress of the pressure sensor 1 is reduced, the internal stress applied to the diaphragm 25 is reduced, and the internal stress is hard to be transmitted to the diaphragm 25. Accordingly, the pressure sensor 1 can exhibit excellent pressure measurement accuracy.

The second sealing layer 462 is disposed on the first sealing layer 461, and an opening on the upper end side of each through-hole 461a is closed by the second sealing layer 462. With this, the pressure reference chamber S is sealed.

A cross-sectional shape of each through-hole 461a is substantially circular. However, the cross-sectional shape of each through-hole 461a is not particularly limited, and may include, for example, a polygon such as a triangle or a quadrangle, an ellipse, an irregular shape, or the like.

As illustrated in FIG. 4, the through-hole 461a has a tapered shape in which a cross-sectional area (diameter) gradually decreases from the pressure reference chamber S side toward the second sealing layer 462 side. As such, the through-hole 461a is formed to have a tapered shape and thus, it is possible to secure sufficient space in the through-hole 461a to more easily deform the through-hole 461a and to make the opening on the upper side of the through-hole 461a sufficiently small. For that reason, it is possible to more reliably close the opening on the upper end side of the through-hole 461a with the second sealing layer 462 while making it easy to deform the first sealing layer 461 in the in-plane direction. In the first embodiment, the through-hole 461a has a tapered shape in the entire region in the axial direction, but at least a portion of the region in the axial direction may have a tapered shape as described above. The shape of the through-hole 461a is not particularly limited, and may be a shape other than the tapered shape described above, for example, a straight shape, an inverted tapered shape, or the like.

As illustrated in FIG. 4, a diameter Rmax (width) of the opening on the lower end side of the through-hole 461a is not particularly limited but, for example, the diameter is preferably 0.6 μm or more and 1.2 μm or less, and more preferably 0.8 μm or more and 1.0 μm or less. With this, it is possible to more securely secure a sufficiently large space in the through-hole 461a and make the first sealing layer 461 more easily deformable. It is possible to prevent the through-hole 461a from becoming excessively large, for example, it is possible to suppress matters that the mechanical strength of the first sealing layer 461 is excessively reduced or the first sealing layer 461 becomes excessively thick in order to secure the mechanical strength of the first sealing layer 461.

On the other hand, the diameter Rmin (width) of the opening on the upper end side of the through-hole 461a is not particularly limited, but the diameter Rmin is preferably, for example, 100 Å or more and 900 Å or less, more preferably 300 Å or more and 700 Å or less. With this, the through-hole 461a is adapted to have a diameter large enough to perform etching for removing a coating layer 444 to be described later and has a diameter so as to be more reliably closed by the second sealing layer 462.

The rate of change in the cross-sectional area (diameter) of the through-hole 461a gradually decreases from the pressure reference chamber S side toward the second sealing layer 462 side. That is, the through-hole 461a is in a state where the inclination of the inner peripheral surface towards the upper side becomes tight and the inner peripheral surface stands substantially vertically at the upper end portion. For that reason, it can be said that the through-hole 461a has a funnel-shaped internal space. When such a configuration is adopted, the diameter of the through-hole 461a can be gradually reduced from the lower side toward the upper side and thus, the diameter Rmin can be controlled with high accuracy. For that reason, it is easy to adjust the diameter Rmin to a target value. That is, it is possible to suppress matters that the diameter Rmin becomes too small to etch and remove the coating layer 444 or the diameter Rmin becomes too large to seal the coating layer 444 with the second sealing layer 462. Accordingly, the coating layer 444 can be more reliably removed through the through-hole 461a and the through-hole 461a can be closed by the second sealing layer 462. The shape of the through-hole 461a is not particularly limited, and for example, the change rate of the cross-sectional area (diameter) may be constant toward the upper side.

As illustrated in FIGS. 1 and 4, the first sealing layer 461 has a frame shape (annular shape) surrounding the lower end side opening of each through-hole 461a and has a frame shaped protruding portion 461b protruding toward the pressure reference chamber S side. For that reason, even when the sealing layer 46 bends toward the diaphragm 25 side and the sealing layer 46 comes into contact with the diaphragm 25, the protruding portion 461b preferentially comes into contact with the diaphragm 25. For that reason, as compared with a case where the protruding portion 461b is not provided, a contact area between the sealing layer 46 and the diaphragm 25 can be reduced and occurrence of “sticking” that the sealing layer 46 sticks in contact with the diaphragm 25 can be effectively suppressed. However, the protruding portion 461b may be omitted.

As illustrated in FIG. 4, a thickness T1 of the first sealing layer 461 is larger than a thickness T2 of the second sealing layer 462 and a thickness T3 of the third sealing layer 463. The plurality of through-holes 461a are disposed in the first sealing layer 461 and thus, the mechanical strength of the first sealing layer 461 is more easily reduced than the other layers (second sealing layer 462 and third sealing layer 463). For that reason, by satisfying the relationship of T1>T2, T3, it is possible to impart sufficient mechanical strength to the first sealing layer 461.

Specifically, the thickness T1 of the first sealing layer 461 is not particularly limited, but is preferably 1 μm or more and 10 μm or less, more preferably 2 μm or more and 7 μm or less, for example. With this, it is possible to prevent the excessive thickening of the first sealing layer 461 while imparting sufficient mechanical strength to the first sealing layer 461. It is possible to more easily form the through-hole 461a having the diameters Rmax and Rmin described above.

On the first sealing layer 461 as described above, the second sealing layer 462 is stacked. The second sealing layer 462 is a layer for mainly sealing the plurality of through-holes 461a provided in the first sealing layer 461. The thickness T2 of the second sealing layer 462 is not particularly limited, but the thickness T2 is preferably 1 μm or more and 5 μm or less, more preferably 1.5 μm or more and 2.5 μm or less, for example. With this, it is possible to more reliably seal the through-hole 461a with the second sealing layer 462 while preventing excessive thickening of the second sealing layer 462.

On the second sealing layer 462 as described above, the third sealing layer 463 is stacked. The third sealing layer 463 is a layer that mainly sandwiches the second sealing layer 462 made of a different material between the third sealing layer 463 and the first sealing layer 461 having the same material, so that the thermal expansion coefficient of the sealing layer 46 is averaged in the thickness direction to suppress bending of the sealing layer 46 in the out-of-plane direction at the time of thermal expansion. With this, in particular, downward bending of the sealing layer 46 can be suppressed and contact between the sealing layer 46 and the diaphragm 25 can be suppressed. In a case where the through-hole 461a cannot be closed by the second sealing layer 462 due to defective film formation of the second sealing layer 462 or the like, the through-hole 461a can be closed by the third sealing layer 463. With this, the pressure reference chamber S can be more reliably sealed.

Here, when the second sealing layer 462 is exposed to the outside, there is a concern that the second sealing layer 462 adsorbs moisture and internal stress of the sealing layer 46 due to environmental humidity is changed. When the internal stress of the sealing layer 46 is changed due to environmental humidity, the internal stress of the diaphragm 25 is also changed according to the change in the internal stress of the sealing layer 46. For that reason, there is a concern that even when the same pressure is received, the measured value varies depending on the environmental humidity and the pressure measurement accuracy of the pressure sensor 1 decreases.

Accordingly, in the first embodiment, the second sealing layer 462 is covered with the third sealing layer 463 and the second sealing layer 462 is airtightly sealed from the outside of the pressure sensor 1. That is, the third sealing layer 463 covers a surface that can be exposed to the outside of the second sealing layer 462 and prevents exposure of the second sealing layer 462 to the outside. With this, the second sealing layer 462 can be protected from moisture and change in the internal stress of the sealing layer 46 due to environmental humidity can be suppressed.

In the first embodiment, a side surface of the second sealing layer 462 is covered with the third sealing layer 463, but is not limited thereto. The side surface of the second sealing layer 462 may be covered with the first sealing layer 461 or covered with both the first sealing layer 461 and the third sealing layer 463. For example, in a case where the second sealing layer 462 is used in an environment hardly affected by humidity, for example, the humidity is constant, the second sealing layer 462 may not be sealed by the third sealing layer 463 and the second sealing layer 462 may be exposed to the outside.

The thickness T3 of the third sealing layer 463 is not particularly limited, but the thickness T3 is preferably, for example, 0.1 μm or more and 10.0 μm or less, more preferably 0.3 μm or more and 1.0 μm or less. With this, it is possible to balance the thickness with the first sealing layer 461 and it is possible to more effectively suppress bending of the sealing layer 46 in the out-of-plane direction at the time of thermal expansion. It is possible to suppress generation of pinholes in the third sealing layer 463 and it is possible to more reliably seal the second sealing layer 462 between the first sealing layer 461 and the third sealing layer 463. For that reason, it is possible to more effectively protect the second sealing layer 462 from moisture. It is possible to prevent excessive thickening of the third sealing layer 463.

Although the sealing layer 46 has been described as above, a configuration of the sealing layer 46 is not particularly limited. For example, another layer may be interposed between the first sealing layer 461 and the second sealing layer 462 or between the second sealing layer 462 and the third sealing layer 463. That is, the sealing layer 46 may have a stacked structure of four or more layers. The third sealing layer 463 may be omitted.

Next, the metal layer 48 will be described in detail. As illustrated in FIG. 1 and FIG. 5, the metal layer 48 is positioned between the side wall portion 4A and the sealing layer 46 and is disposed in a frame shape constituting a ring in plan view of the substrate 2. The metal layer 48 is not limited to a member constituting a closed ring in plan view, and may have a shape in which a portion of the ring is missing, for example, like a C-shape ring.

The inner peripheral end 48a (inner peripheral end of the guard ring 441) of the metal layer 48 is positioned between the through-hole 461a and the outer edge of the diaphragm 25 in plan view of the substrate 2. More specifically, in plan view of the substrate 2, the inner peripheral end 48a of the metal layer 48 is positioned between a through-hole disposition region S3 (region overlapping with the central portion of the diaphragm 25), in which the plurality of through-holes 461a are disposed, and the outer edge of the diaphragm 25. The metal layer 48 may have a frame shape in which a portion of the metal layer 48 is missing in the periphery direction. In the metal layer 48, the entire periphery of the inner peripheral end 48a is desirably positioned between the through-hole 461a and the outer edge of the diaphragm 25 (inner wall surface of recess portion 24). However, a portion (for example, about 30% or less of the entire periphery) of the entire periphery of the inner peripheral end 48a may be positioned outside the diaphragm 25.

When such a configuration is adopted, a volume (volume of a metal portion) of the metal layer 48 can be reduced as compared with the configuration of the related art. The metal portion such as the metal layer 48 has a large coefficient of thermal expansion with respect to a surrounding portion thereof and thus, the volume (volume of the metal portion) of the metal layer 48 is reduced so as to make it possible to effectively reduce a change in internal stress due to thermal expansion of the metal layer 48. For that reason, the pressure sensor 1 becomes able to suppress the change in the internal stress applied to the diaphragm 25 due to the environmental temperature and exhibit excellent pressure measurement accuracy.

Here, as illustrated in FIG. 6, when the entirety of the metal layer 48 is removed, the effect described above becomes more prominent. However, in this case, a gap S2 is generated between the side wall portion 4A and the sealing layer 46, so that the sealing layer 46 easily bends toward the lower side (diaphragm 25 side). As described above, when the sealing layer 46 bends downward and comes into contact with the diaphragm 25, the pressure measurement accuracy of the pressure sensor 1 is reduced. Accordingly, in the pressure sensor 1, the volume of the metal layer 48 is suppressed to the minimum while leaving the metal layer 48 so as not to allow a gap to be formed between the side wall portion 4A and the sealing layer 46 and suppressing the downward bending of the sealing layer 46, so that it is possible to suppress the change in the internal stress applied to the diaphragm 25 due to the environmental temperature. As such, the pressure sensor 1 is adapted to have a configuration able to exhibit excellent pressure measurement accuracy by leaving the metal layer 48 moderately.

As illustrated in FIG. 1, the metal layer 48 includes a base portion 481 which has a portion positioned between the side wall portion 4A and the sealing layer 46 and a connection portion 482 which is positioned between the base portion 481 and the substrate 2 and connected to the base portion 481. The inner peripheral end of the base portion 481 constitutes the inner peripheral end 48a of the metal layer 48. The base portion 481 is disposed so as to fill the gap between the side wall portion 4A and the sealing layer 46 and supports the sealing layer 46 from the lower side (diaphragm 25 side). With this, it is possible to suppress downward bending of the sealing layer 46 as described above.

The metal layer 48 is provided so as to protrude into the pressure reference chamber S from the side wall portion 4A. In other words, the metal layer 48 has a portion positioned between the pressure reference chamber S and the sealing layer 46. With this, the sealing layer 46 can be effectively supported from below by the metal layer 48 and downward bending of the sealing layer 46 can be more effectively suppressed. In particular, as described above, the inner peripheral end 48a of the metal layer 48 is positioned between the through-hole disposition region S3 and the outer edge of the diaphragm 25 (inner wall surface of the recess portion 24) and thus, the sealing layer 46 can be more effectively supported by the metal layer 48 from below.

The connection portion 482 is positioned between the base portion 481 and the conductive film 33 and connects the base portion 481 and the conductive film 33. The connection portion 482 has a function as an etching stopper at the time of removing the sacrificial layer G which fills the pressure reference chamber S to the middle of manufacturing, as will be described in a manufacturing method to be described later. With this, it is possible to define a size and shape of the pressure reference chamber S and to make it easy to form the pressure reference chamber S having a desired shape. In particular, the pressure reference chamber S can be prevented from being further enlarged by the connection portion 482 and thus, it is possible to effectively suppress the pressure reference chamber S from becoming excessively large and make it easy for the sealing layer 46 to bend. However, the configuration of the connection portion 482 is not particularly limited, and a configuration in which the connection portion 482 is not connected to the conductive film 33 may be adopted, for example. The connection portion 482 may be omitted.

As illustrated in FIG. 1, the connection portion 482 is embedded in the side wall portion 4A. In other words, the side wall portion 4A is disposed not only on the outer peripheral side of the connection portion 482 but also on the inner peripheral side (that is, between the pressure reference chamber S and the side wall portion 4A). As such, thermal expansion of the connection portion 482 can be suppressed by surrounding the connection portion 482 with the side wall portion 4A. For that reason, it is possible to effectively reduce the change in the internal stress due to the thermal expansion of the metal layer 48. Accordingly, the pressure sensor 1 becomes able to suppress the change in the internal stress applied to the diaphragm 25 due to the environmental temperature and exhibit excellent pressure measurement accuracy. However, for example, the side wall portion 4A on the inner peripheral side of the connection portion 482 may be omitted and the inner periphery of the connection portion 482 may face the pressure reference chamber S.

Next, the configuration of the metal layer 48 will be described in more detail. As described above, the metal layer 48 includes the guard ring 421 of the wiring layer 42 and the guard ring 441 of the wiring layer 44. As illustrated in FIG. 7, the guard ring 421 is provided so as to penetrate through the interlayer insulating film 43, and includes a contact portion 421a having a recessed shape and connected to the conductive film 33 and a flange portion 421b provided on the interlayer insulating film 41 and disposed around the contact portion 421a. The flange portion 421b has an inner portion 421b′ positioned on the pressure reference chamber S side with respect to the contact portion 421a and an outer portion 421b″ positioned on the side opposite to the inner portion 421b′. The guard ring 441 is provided so as to penetrate through the interlayer insulating film 43, and includes a contact portion 441a having a recessed shape and connected to the contact portion 421a of the guard ring 421 and a flange portion 441b provided on the interlayer insulating film 41 and disposed around the contact portion 441a. The flange portion 441b has an inner portion 441b′ positioned at the pressure reference chamber S side than the contact portion 441a and an outer portion 441b″ positioned on the side opposite to the inner portion 441b′. In the metal layer 48 having such a configuration, it can be said that the base portion 481 is formed by the guard ring 441 and the connection portion 482 is formed by the guard ring 421.

Although the peripheral structured body 4 has been described as above, the configuration of the peripheral structured body 4 is not particularly limited. For example, in the first embodiment, although the configuration in which each of the interlayer insulating film and the wiring layer has two layers, the number of layers of the interlayer insulating film and the wiring layer is not particularly limited.

The pressure sensor 1 has been described as above. As described above, such a pressure sensor 1 includes the substrate 2 having the diaphragm 25 bent and deformed by pressure reception, the side wall portion 4A disposed on the upper surface (one surface) side of the substrate 2 and surrounding the diaphragm 25 in plan view of the substrate 2, the sealing layer 46 disposed to face the diaphragm 25 with the pressure reference chamber S (space) interposed therebetween and sealing the pressure reference chamber S, and the frame shaped metal layer 48 positioned between the side wall portion 4A and the sealing layer 46. The sealing layer 46 includes a first sealing layer 461 having the through-hole 461a which faces the pressure reference chamber S and a second sealing layer 462 positioned on the side opposite to the pressure reference chamber S with respect to the first sealing layer 461 and sealing the through-hole 461a. In plan view of the substrate 2, the inner peripheral end 48a of the metal layer 48 is positioned between the through-hole 461a and the outer edge of the diaphragm 25. With this, it is possible to reduce the volume (volume of the metal portion) of the metal layer 48 as compared with the configuration of the related art. The metal portion has a large coefficient of thermal expansion with respect to a surrounding portion thereof and thus, the volume (volume of the metal portion) of the metal layer 48 is reduced so as to make it possible to effectively reduce the change in the internal stress due to the thermal expansion of the metal layer 48. For that reason, the pressure sensor 1 becomes able to suppress the change in the internal stress applied to the diaphragm 25 due to the environmental temperature and exhibit excellent pressure measurement accuracy.

As described above, in the pressure sensor 1, the through-hole 461a overlaps with the central portion of the diaphragm 25 in plan view of the substrate 2. With this, sufficient space can be secured between the through-hole 461a and the outer edge of the diaphragm 25 and the inner peripheral end 48a of the metal layer 48 can be easily positioned between the through-hole 461a and the outer edge of the diaphragm 25.

As described above, in the pressure sensor 1, the metal layer 48 includes the base portion 481 having a portion positioned between the side wall portion 4A and the sealing layer 46 and the connection portion 482 positioned between the base portion 481 and the substrate 2 and connected to the base portion 481. With this, it is possible to cause the metal layer 48 to function as an etching stopper when the sacrificial layer G filling the pressure reference chamber S to the middle of manufacturing is removed. Accordingly, the size and shape of the pressure reference chamber S can be defined by the metal layer 48 and it becomes easy to form the pressure reference chamber S having a desired shape.

As described above, in the pressure sensor 1, the connection portion 482 is embedded in the side wall portion 4A. With this, the thermal expansion of the connection portion 482 can be suppressed. For that reason, it is possible to effectively reduce the change in the internal stress due to the thermal expansion of the metal layer 48. Accordingly, the pressure sensor 1 becomes able to suppress the change in the internal stress applied to the diaphragm 25 due to the environmental temperature and exhibit excellent pressure measurement accuracy.

As described above, the metal layer 48 contains aluminum in the pressure sensor 1. With this, the metal layer 48 can be easily formed in a semiconductor process such as a manufacturing method to be described later.

As described above, in the pressure sensor 1, the sealing layer 46 includes the third sealing layer 463 positioned on the side opposite to the pressure reference chamber S with respect to the second sealing layer 462. With this, in a case where the through-hole 461a cannot be closed by the second sealing layer 462 due to defective film formation of the second sealing layer 462 or the like, the through-hole 461a can be closed by the third sealing layer 463. For that reason, the pressure reference chamber S can be more reliably sealed.

Next, a manufacturing method of the pressure sensor 1 will be described. As illustrated in FIG. 8, the manufacturing method of the pressure sensor 1 includes a preparation process of preparing the substrate 2, a sensor portion disposition process of disposing the sensor portion 5 on the substrate 2, a sacrificial layer disposition process of disposing a sacrificial layer G and a side wall portion 4A positioned around the sacrificial layer G on the upper surface side of the substrate 2, a metal layer disposition process of disposing the metal layer 480 which faces the substrate 2 via the sacrificial layer G and has a through-hole 445 facing the sacrificial layer G, a sacrificial layer removal process of removing the sacrificial layer G through the through-hole 445, a first sealing layer disposition process of disposing the first sealing layer 461 having the through-hole 461a on the upper side of the metal layer 480, a metal layer removal process of removing a portion of the metal layer 480 via the through-hole 461a, a second sealing layer disposition process of disposing the second sealing layer 462 on the upper side of the first sealing layer 461, a third sealing layer disposition process of disposing the third sealing layer 463 on the upper side of the second sealing layer 462, and a diaphragm formation process of forming the diaphragm 25 on the substrate 2.

### Preparation Process

First, as illustrated in FIG. 9, the substrate 2 composed of an SOI substrate in which the first layer 21, the second layer 22, and the third layer 23 are stacked is prepared. At this process, the diaphragm 25 is not formed in the diaphragm forming region 250 of the substrate 2. Next, for example, the surface of the third layer 23 is thermally oxidized to form the first insulating film 31 composed of a silicon oxide film on the upper surface of the substrate 2.

### Sensor Portion Disposition Process

Next, as illustrated in FIG. 10, impurities such as phosphorus, boron, or the like is injected into the upper surface of the substrate 2 to form the sensor portion 5. Next, the second insulating film 32 and the conductive film 33 are formed on the upper surface of the first insulating film 31 by a sputtering method, a CVD method, or the like.

### Sacrificial Layer Disposition Process

Next, as illustrated in FIG. 11, the interlayer insulating film 41, the wiring layer 42, the interlayer insulating film 43, the wiring layer 44, the surface protective film 45, and the terminal 47 are formed in order on the substrate 2 by the sputtering method, the CVD method, or the like to form a predetermined pattern. With this, the sacrificial layer G that overlaps the diaphragm forming region 250 in plan view of the substrate 2 and is configured with the interlayer insulating films 41 and 43, the frame shaped side wall portion 4A positioned around the sacrificial layer G and surrounding the sacrificial layer G, and the metal layer 480 are obtained. The metal layer 480 includes the metal layer 48 which is configured with the guard ring 421 formed from the wiring layer 42 and the guard ring 441 formed from the wiring layer 44 and the coating layer 444 which is formed from the wiring layer 44 and faces the substrate 2 with the sacrificial layer G interposed therebetween. The coating layer 444 is integrally formed with the guard ring 441 and has a plurality of through-holes 445 facing the sacrificial layer G. The side wall portion 4A and the sacrificial layer G are spatially separated by the metal layer 48. In the first embodiment, the interlayer insulating films 41 and 43 are made of silicon oxide and the wiring layers 42 and 44 are made of aluminum.

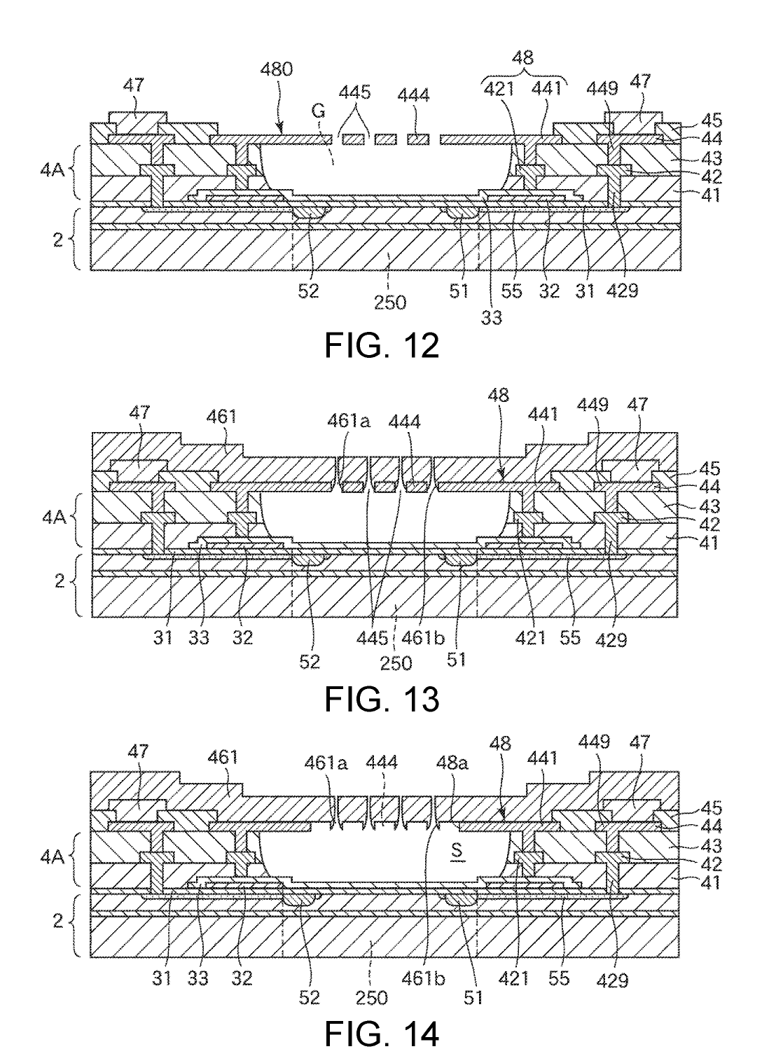

Next, the substrate 2 is exposed to an etching solution such as buffered hydrofluoric acid or the like. With this, as illustrated in FIG. 12, the sacrificial layer G is removed by etching through the through-hole 445. In this case, the metal layer 48 functions as an etching stopper and unintentional removal of the side wall portion 4A positioned outside the metal layer 48 is suppressed. In the first embodiment, a portion of the sacrificial layer G is not removed and is left as the side wall portion 4A. With this, the connection portion 482 of the metal layer 48 is embedded in the side wall portion 4A. Here, wet etching in the sacrificial layer disposition process is isotropic etching and thus, more sacrificial layer G is removed on the coating layer 444 side than on the substrate 2 side. For that reason, the formed space has a tapered shape in which an area gradually increases from the substrate 2 side to the coating layer 424 side. In this process, all of the sacrificial layer G may be removed.

### First Sealing Layer Disposition Process

Next, as illustrated in FIG. 13, the first sealing layer 461 having the through-hole 461a is formed on the upper surfaces of the metal layer 480 and the surface protective film 45. A film forming method of the first sealing layer 461 is not particularly limited, and various film forming methods (vapor growth method) such as a sputtering method, a CVD method, or the like can be used, for example.

Here, description will be made on the first sealing layer disposition process in detail. When the first sealing layer 461 is grown on the metal layer 480, the through-hole 445 is sharply closed at the beginning, but as the thickness of the first sealing layer 461 increases, the momentum of the through-hole 445 decreases, and the through-hole 445 is hardly closed from around where the first sealing layer 461 exceeds a certain thickness. This is because it is supposed that the sacrificial layer G is removed in the previous process to form space below the through-hole 445 and Si atoms passed through the through-hole 445 are allowed to escape into the space so as to suppress matters that the through-hole 445 is closed. As such, the first sealing layer 461 is formed in a state where space is formed below the metal layer 480 so as to make it possible to form the through-hole 461a easily and more certainly. A portion of the first sealing layer 461 enters the through-hole 445 so as to form the frame shaped protruding portion 461b. Thus, it can be said that the metal layer 480 (particularly, coating layer 444) has a function as an underlying layer for forming the through-hole 461a and the protruding portion 461b in the first sealing layer 461.

### Metal Layer Removal Process

Next, the substrate 2 is exposed to an etchant such as mixed acid of phosphoric acid, acetic acid, and nitric acid and the coating layer 444 included in the metal layer 480 is removed through the through-hole 461a. With this, as illustrated in FIG. 14, the pressure reference chamber S is formed and the metal layer 48 is obtained from the remaining portion of the metal layer 480. The metal layer 48 obtained by doing as described above has a frame shape and the inner peripheral end 48a thereof is positioned between the through-hole 461a and the outer edge of the diaphragm forming region 250. The coating layer 444 is positioned in the vicinity of the through-hole 461a and thus, the coating layer 444 is preferentially removed by etching than other portions (guard rings 421 and 441) of the metal layer 480. For that reason, in the metal layer removal process, the coating layer 444 can be removed while leaving the metal layer 48 (guard rings 421 and 441).

### Second Sealing Layer Disposition Process

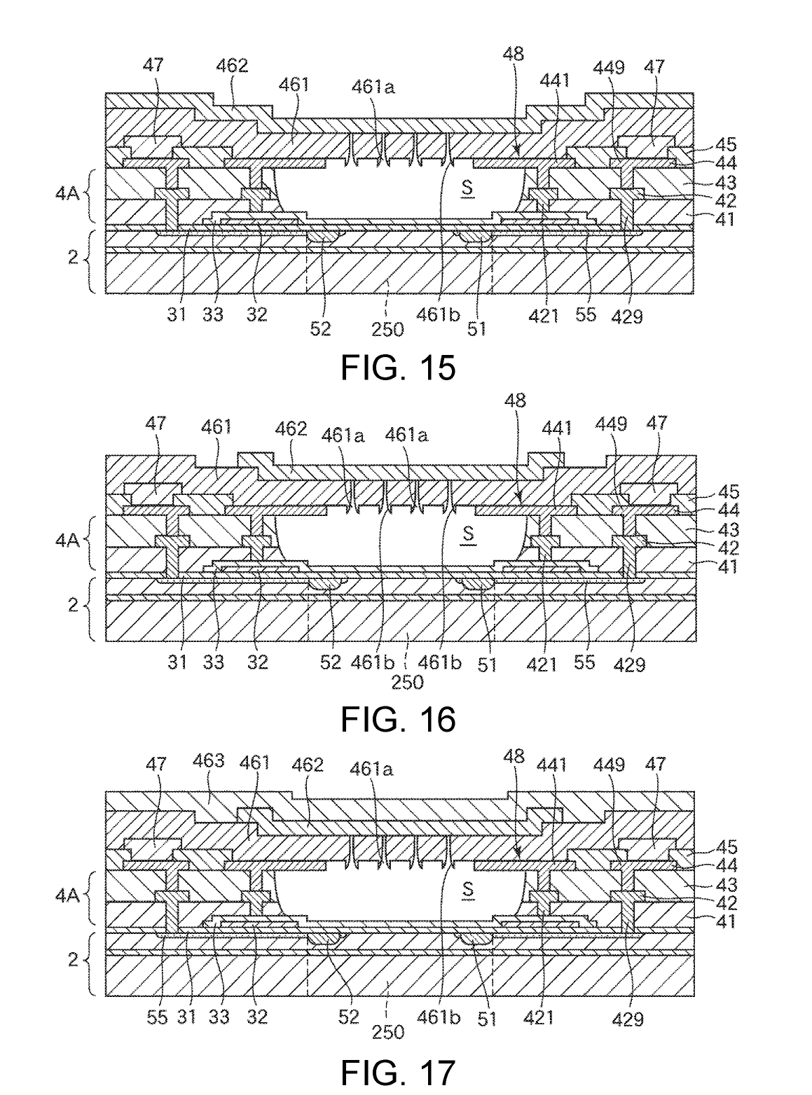

Next, in a state where the pressure reference chamber S is set in a vacuum state through the through-hole 461a, as illustrated in FIG. 15, the second sealing layer 462 is formed on the upper surface of the first sealing layer 461 and the through-hole 461a is sealed. The film forming method of the second sealing layer 462 is not particularly limited, and various film forming methods (vapor growth method) such as a sputtering method and a CVD method can be used, for example.

Next, as illustrated in FIG. 16, the second sealing layer 462 is patterned by using the photolithography technique and etching technique and the outer edge of the second sealing layer 462 is formed to be positioned inside the outer edge of the first sealing layer 461. As a patterning method of the second sealing layer 462, wet etching using an etchant such as buffered hydrofluoric acid is preferably used. With this, it is possible to secure a large etching selection ratio between the second sealing layer 462 and the first sealing layer 461 and to pattern substantially only the second sealing layer 462.

### Third Sealing Layer Disposition Process

Next, as illustrated in FIG. 17, the third sealing layer 463 is formed on the upper surfaces of the first sealing layer 461 and the second sealing layer 462. With this, the second sealing layer 462 is sealed by the first sealing layer 461 and the third sealing layer 463. The film forming of the third sealing layer 463 is not particularly limited, and various film forming methods (vapor growth method) such as a sputtering method, a CVD method and the like can be used, for example.

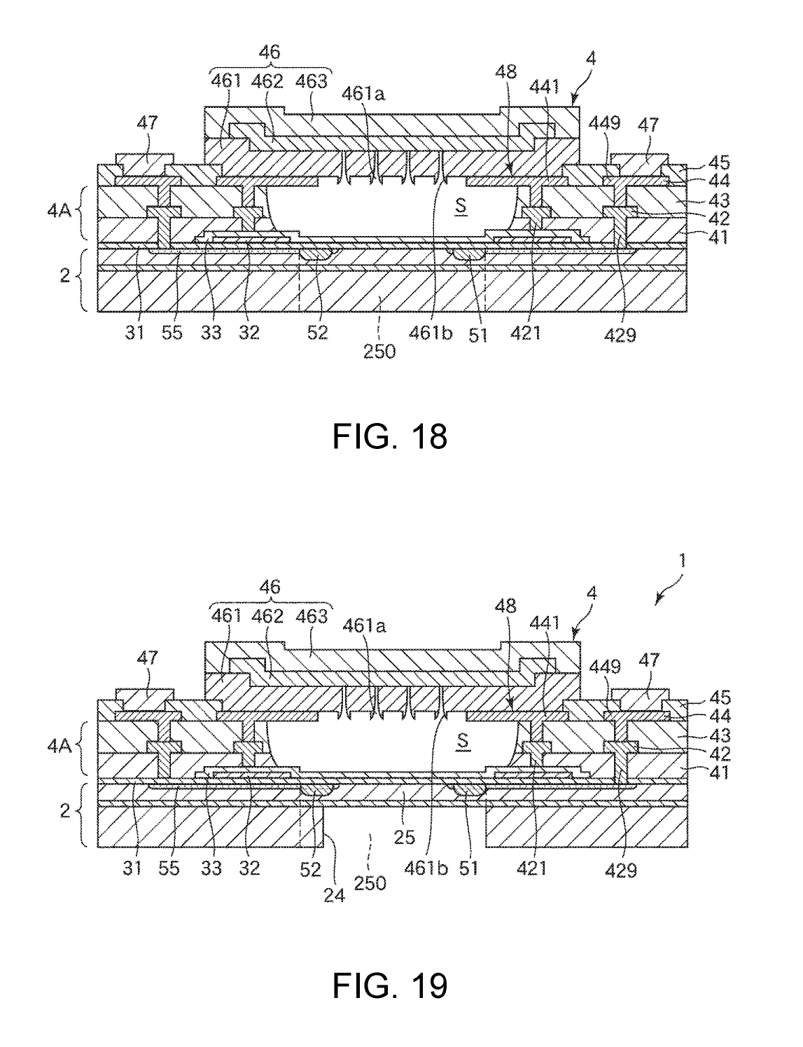

Next, as illustrated in FIG. 18, the first sealing layer 461 and the third sealing layer 463 are simultaneously patterned by the photolithography technique and etching technique. With this, the sealing layer 46 is obtained. The first sealing layer 461 and the third sealing layer 463 are made of the same material so that the sealing layers 461 and 463 can be patterned at the same time. For that reason, the number of manufacturing processes of the pressure sensor 1 can be reduced and manufacturing of the pressure sensor 1 becomes easier.

### Diaphragm Formation Process

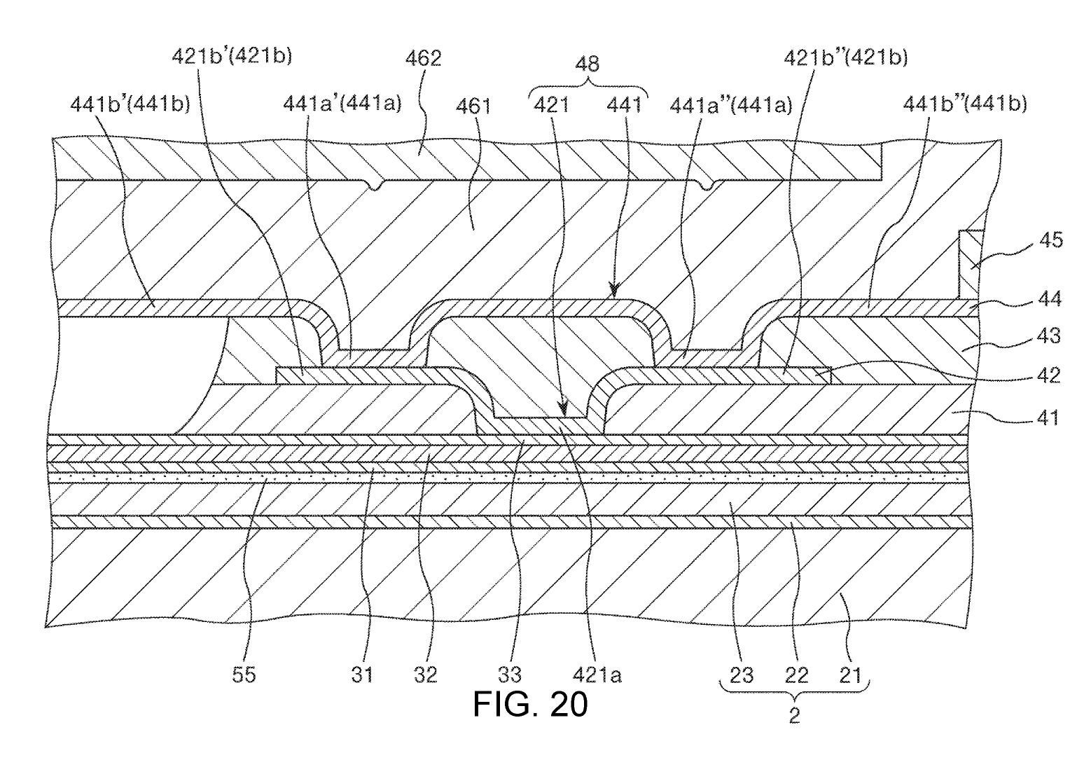

Next, as illustrated in FIG. 19, the first layer 21 is etched by, for example, a dry etching (in particular, silicon deep etching) method to form the recess portion 24 which opens to the lower surface in the diaphragm forming region 250 and obtain the diaphragm 25. With this, the pressure sensor 1 is obtained. The order of the diaphragm formation process is not particularly limited, and the diaphragm formation process may be performed, for example, prior to the sensor portion disposition process, or between the sensor portion disposition process and the third sealing layer disposition process, for example.

The manufacturing method of the pressure sensor 1 has been described as above. As described above, the manufacturing method of the pressure sensor 1 includes a process of preparing the substrate 2 having the diaphragm forming region 250, a process of disposing the sacrificial layer G overlapping with the diaphragm forming region 250 in plan view of the substrate 2 and the side wall portion 4A positioned around the sacrificial layer G on the upper surface (one surface) side of the substrate 2, a process of disposing the metal layer 480 which faces the substrate 2 with the sacrificial layer G interposed therebetween and has the through-hole 445 (first through-hole) facing the sacrificial layer G, a process of removing the sacrificial layer G using the through-hole 445, a process of disposing the first sealing layer 461 having the through-hole 461a (second through-hole) on the side opposite to (upper side) the substrate 2 with respect to the metal layer 480, a process of forming the metal layer 480 to have a frame shape in which the inner peripheral end 48a is positioned between the through-hole 461a and the outer edge of the diaphragm forming region 250 in plan view of the substrate 2 by removing a portion of the metal layer 480 using the through-hole 461a, a process of disposing the second sealing layer 462 which seals the through-hole 461a on the side opposite (upper side) to the substrate 2 with respect to the first sealing layer 461, and a process of forming the diaphragm 25 bent and deformed by pressure reception in the diaphragm forming region 250. With this, the pressure sensor 1 in which the volume (volume of the metal portion) of the metal layer 48 is reduced as compared with the configuration of the related art is obtained. The metal portion has a large coefficient of thermal expansion with respect to a surrounding portion and thus, the volume (volume of the metal portion) of the metal layer 48 is reduced so as to make it possible to effectively reduce the change in the internal stress due to the thermal expansion of the metal layer 48. For that reason, the pressure sensor 1 becomes able to suppress the change in the internal stress applied to the diaphragm 25 due to the environmental temperature and exhibit excellent pressure measurement accuracy.

### Second Embodiment

Next, a pressure sensor according to a second embodiment of the invention will be described.

FIG. 20 is a cross-sectional view illustrating a pressure sensor according to a second embodiment of the invention.

The pressure sensor 1 according to the second embodiment is substantially the same as the pressure sensor 1 of the first embodiment except that the configuration of the metal layer 48 is different.

In the following, regarding the pressure sensor 1 of the second embodiment, description will be mainly made on differences from the first embodiment described above and description of similar matters between the first and second embodiments will be omitted. The same reference numerals are given to the same configurations as those in the embodiment described above.

FIG. 20 is a cross-sectional view corresponding to FIG. 7 of the first embodiment described above and illustrates a cross section of the metal layer 48. As illustrated in FIG. 20, in the second embodiment, the guard ring 441 includes two recess shaped contact portions 441a provided to penetrate through the interlayer insulating film 43 and connected to the guard ring 421 and a flange portion 441b provided on the interlayer insulating film 43 and disposed around the contact portions 441a. The two contact portions 441a forma frame shape surrounding the pressure reference chamber S in plan view of the substrate 2 and are concentrically disposed. When the contact portion 441a positioned on the inner side is denoted by a “contact portion 441a′” and the contact portion 441a positioned on the outer side is denoted by a “contact portion 441a″”, the contact portion 441a′ is connected to the inner portion 421b′ of the flange portion 421b and the contact portion 441a″ is connected to the outer portion 421b″ of the flange portion 421b.

For example, when it is attempted to connect the contact portion 441a to the contact portion 421a as in the first embodiment described above, the contact portion 441a may become deep to the extent that obstructs subsequent film formation depending on the thickness of the interlayer insulating films 41 and 43, in some cases. For that reason, the step coverage (step coating performance) of the sealing layer 46 formed on the contact portion 441a is deteriorated, for example, there is a concern that mechanical strength of the peripheral structured body 4 and air tightness of the pressure reference chamber S are deteriorated. In contrast, in the second embodiment, the contact portion 441a is connected to the flange portion 421b and thus, the step coverage of the sealing layer 46 becomes better as compared with the first embodiment, so that it is possible to more reliably suppress reduction in the mechanical strength of the peripheral structured body 4 and airtightness of the pressure reference chamber S.

Also, in the second embodiment as described above, it is possible to exhibit the same effects as those of the first embodiment described above.

### Third Embodiment

Next, a pressure sensor according to a third embodiment of the invention will be described.

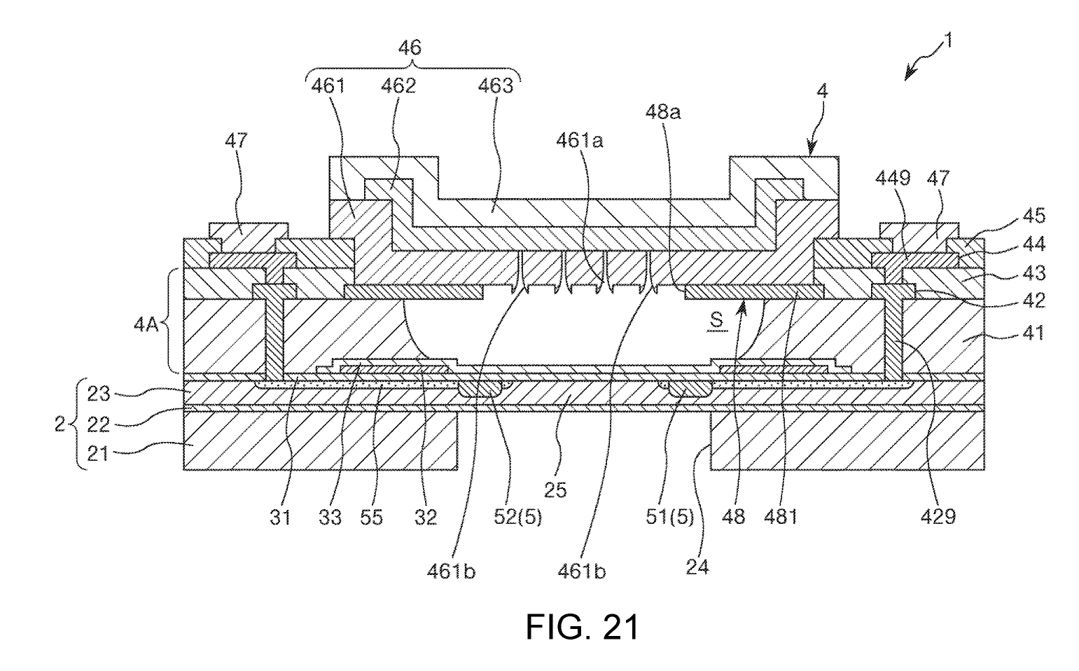

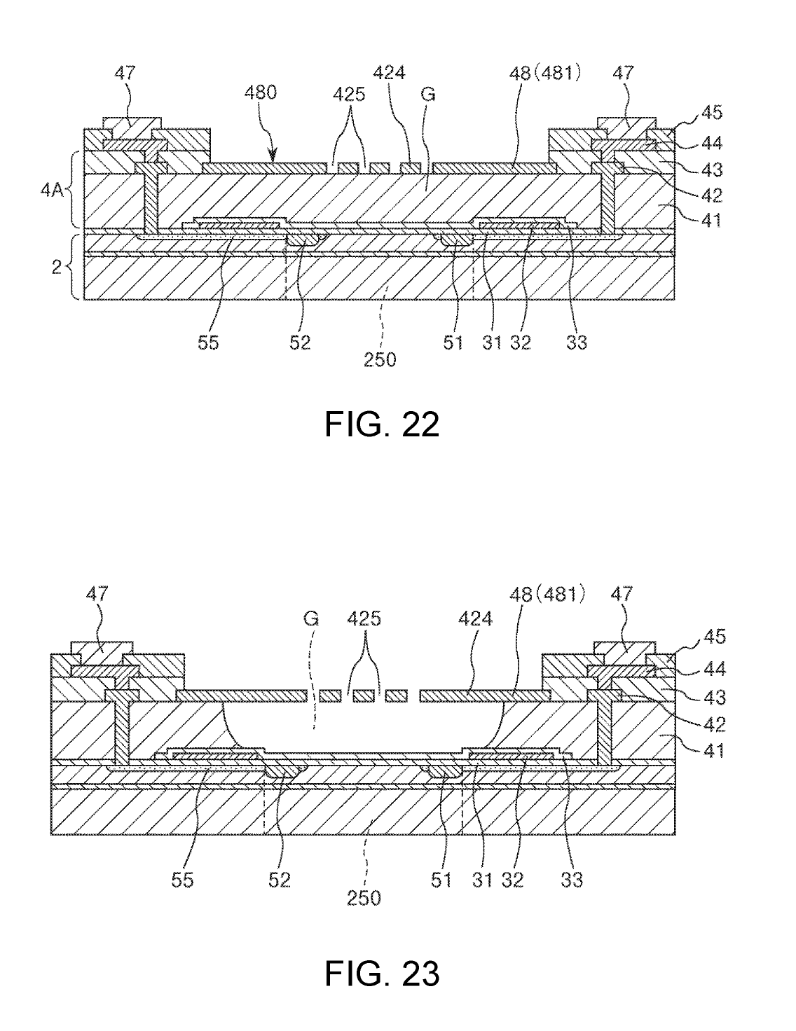

FIG. 21 is a cross-sectional view illustrating a pressure sensor according to a third embodiment of the invention. FIGS. 22 to 25 are cross-sectional views for explaining a manufacturing method of the pressure sensor illustrated in FIG. 21, respectively.

The pressure sensor 1 according to the third embodiment is substantially the same as the pressure sensor 1 of the first embodiment described above except that the configuration of the metal layer 48 is different.

In the following, regarding the pressure sensor 1 of the third embodiment, description will be mainly made on differences from the first embodiment described above and description of similar matters between the first and third embodiments will be omitted. The same reference numerals are given to the same configurations as those in the embodiments described above.

As illustrated in FIG. 21, in the pressure sensor 1 of the third embodiment, the metal layer 48 includes the base portion 481 which is disposed on the interlayer insulating film 43 and includes a portion positioned between the side wall portion 4A and the sealing layer 46 and a portion that protrudes into the pressure reference chamber S from the side wall portion 4A. That is, the pressure sensor 1 of the third embodiment has a configuration in which the connection portion 482 is omitted from the configuration of the first embodiment described above. With this, it is possible to reduce the volume (volume of the metal portion) of the metal layer 48, as compared with the first embodiment described above. For that reason, the pressure sensor 1 becomes able to suppress the change in internal stress applied to the diaphragm 25 due to an environmental temperature and exhibit excellent pressure measurement accuracy. Depending on the thickness of the interlayer insulating film 43, the interlayer insulating film 43 may have a stacked structure of two or more layers, and in that case, a wiring layer may be disposed between the layers.

Next, a manufacturing method of the pressure sensor 1 of the third embodiment will be described. Similar to the first embodiment described above, the manufacturing method of the pressure sensor 1 of the third embodiment includes a preparation process, a sensor portion disposition process, a sacrificial layer disposition process, a metal layer disposition process, a sacrificial layer removal process, a first sealing layer disposition process, a metal layer removal process, a second sealing layer disposition process, a third sealing layer disposition process, and a diaphragm formation process. Among these processes, the sacrificial layer disposition process to the sacrificial layer removal process are different from the first embodiment described above and thus, in the following, description will be made only on the sacrificial layer disposition process to the metal layer removal process.

### Sacrificial Layer Disposition Process

As illustrated in FIG. 22, the interlayer insulating film 41, the wiring layer 42, the interlayer insulating film 43, the wiring layer 44, the surface protective film 45, and the terminal 47 are formed in order on the substrate 2 by the sputtering method, the CVD method, or the like to form a predetermined pattern. With this, the sacrificial layer G that overlaps with the diaphragm forming region 250 in plan view of the substrate 2 and is configured with the interlayer insulating film 41, the frame shaped side wall portion 4A positioned around the sacrificial layer G and surrounding the sacrificial layer G, and the metal layer 480 are obtained. The metal layer 480 includes the metal layer 48 having the base portion 481 formed from the wiring layer 42 and the coating layer 424 formed from the wiring layer 42 and facing the substrate 2 with the sacrificial layer G interposed between the coating layer 424 and the substrate 2. The coating layer 424 is formed integrally with the base portion 481 and has through-holes 425 facing the sacrificial layer G.

Next, the substrate 2 is exposed to etching solution such as buffered hydrofluoric acid or the like. With this, as illustrated in FIG. 23, the sacrificial layer G is removed by etching through the through-holes 425. In this case, the sacrificial layer G is removed more on the coating layer 424 side than on the substrate 2 side. For that reason, formed space has a tapered shape in which an area gradually increases from the substrate 2 side to the coating layer 424 side.

### First Sealing Layer Disposition Process

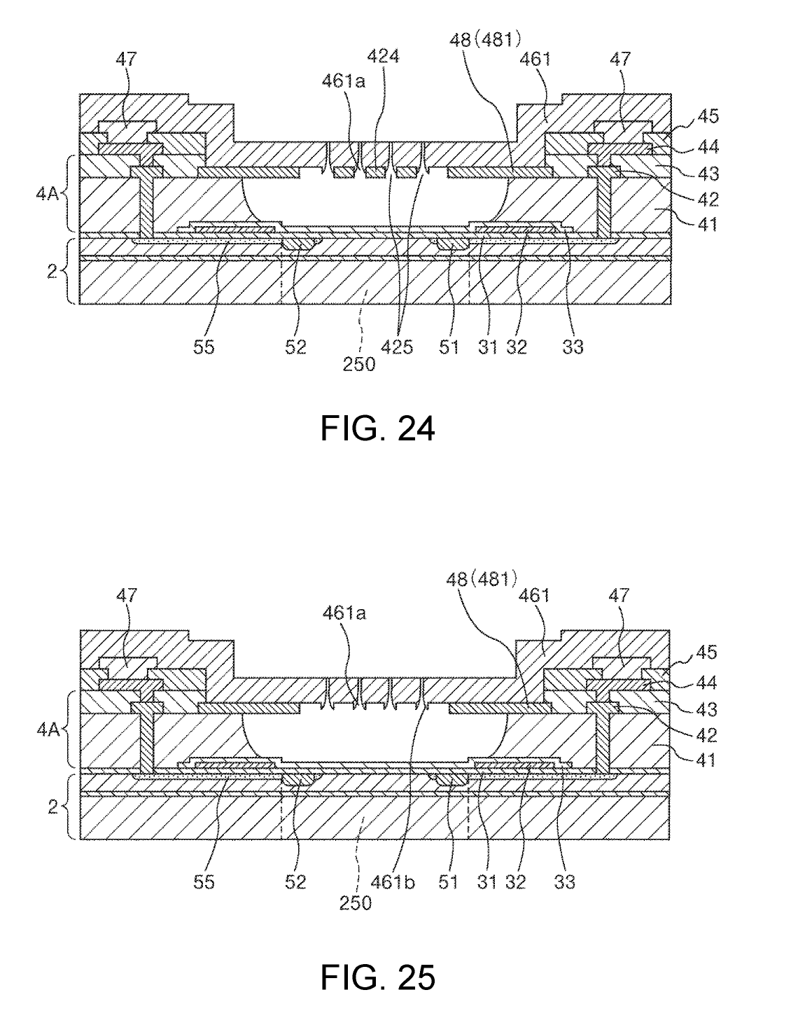

Next, as illustrated in FIG. 24, the first sealing layer 461 having through-holes 461a is formed on the upper surfaces of the metal layer 480 and the surface protective film 45. A film forming method of the first sealing layer 461 is not particularly limited, and various film forming methods (vapor growth method) such as the sputtering method, the CVD method, or the like can be used, for example.

### Metal Layer Removal Process

Next, the substrate 2 is exposed to etching solution such as mixed acid of phosphoric acid, acetic acid, and nitric acid and the coating layer 424 included in the metal layer 480 is removed through the through-holes 461a. With this, as illustrated in FIG. 25, the pressure reference chamber S is formed and the metal layer 48 is obtained from the remaining portion of the metal layer 480.

Also, in the third embodiment as described above, it is possible to exhibit the same effects as those of the first embodiment described above.

### Fourth Embodiment

Next, a pressure sensor module according to a fourth embodiment of the invention will be described.

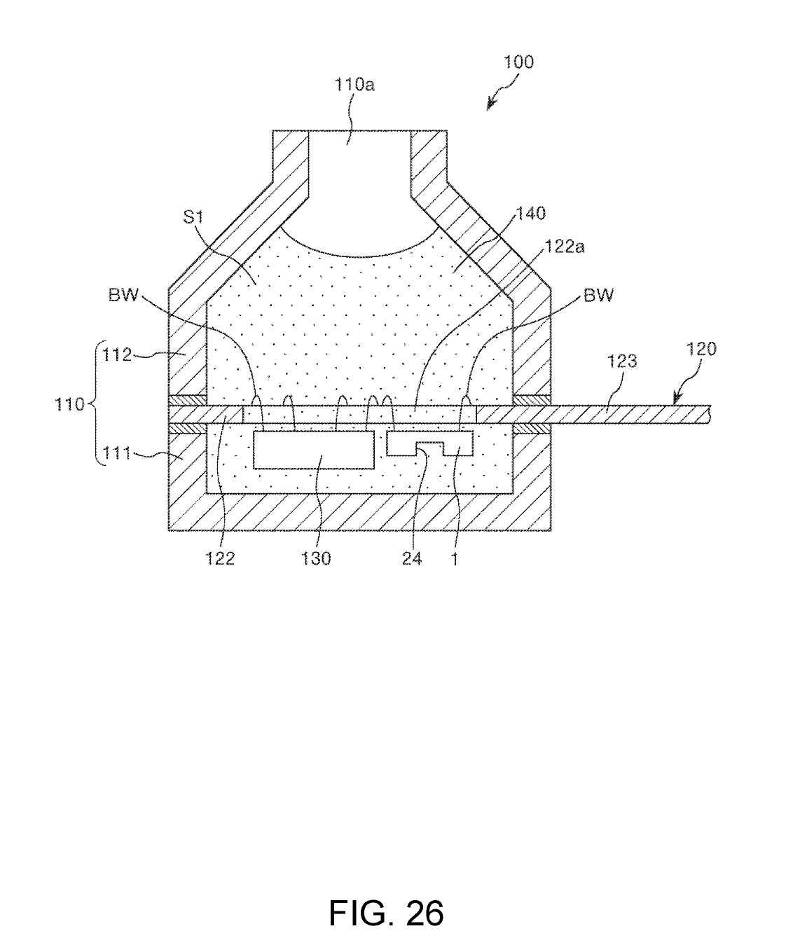

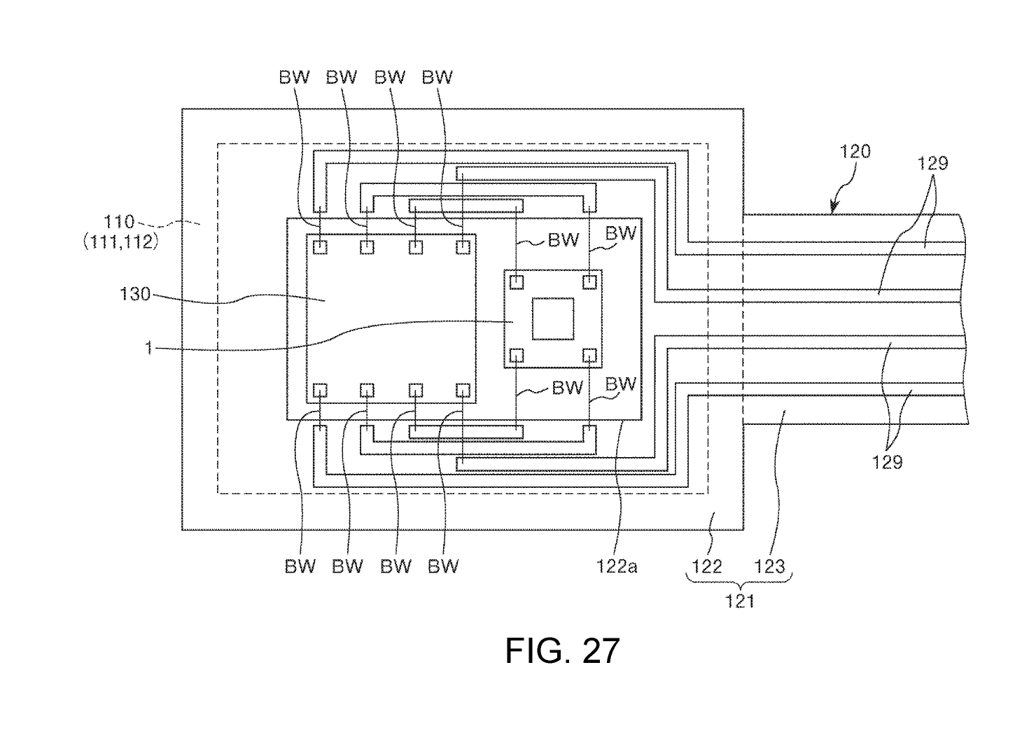

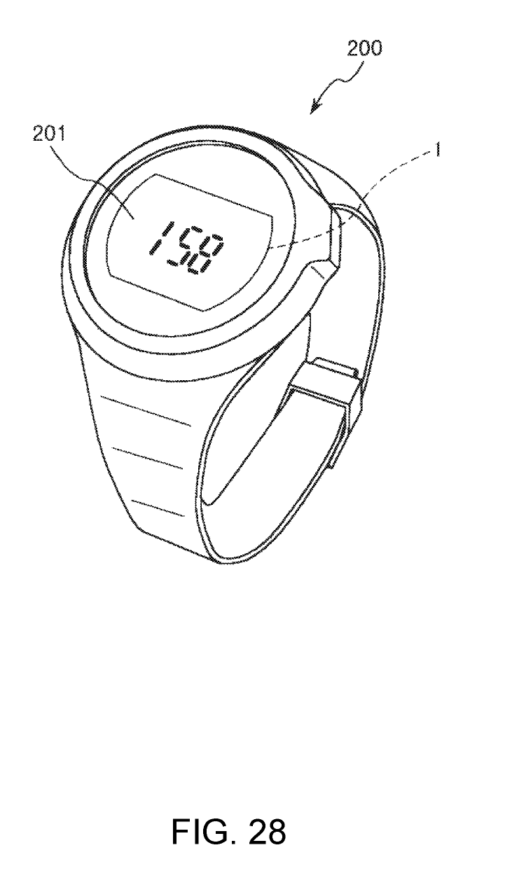

FIG. 26 is a cross-sectional view illustrating a pressure sensor module according to a fourth embodiment of the invention. FIG. 27 is a plan view of a support substrate included in the pressure sensor module illustrated in FIG. 26.

In the following, regarding the pressure sensor module of the fourth embodiment, description will be mainly made on differences from the embodiments described above and description of similar matters between the fourth embodiment and the embodiments described above will be omitted.

As illustrated in FIG. 26, a pressure sensor module 100 includes a package 110 having internal space S1, a support substrate 120 disposed by being drawn out from the internal space S1 to the outside of the package 110, a circuit element 130 and a pressure sensor 1 which are supported by the support substrate 120 within the internal space S1, and a filling portion 140 which is formed by filling the inner space S1 with a filler material to be described later. According to such a pressure sensor module 100, the pressure sensor 1 can be protected by the package 110 and the filling portion 140. As the pressure sensor 1, for example, those of the embodiments described above can be used.

The package 110 has a base 111 and a housing 112, and the base 111 and the housing 112 are joined to each other via an adhesive layer by sandwiching the support substrate 120 between the base 111 and the housing 112. The package 110 formed as such has an opening 110a formed in the upper end portion thereof and the internal space S1 communicating with the opening 110a.

The constituent materials of the base 111 and the housing 112 are not particularly limited and include, for example, insulating materials such as various ceramics, such as oxide ceramics such as alumina, silica, titania, and zirconia, nitride ceramics such as silicon nitride, aluminum nitride, and titanium nitride, and various resin materials such as polyethylene, polyamide, polyimide, polycarbonate, acrylic resin, ABS resin, and epoxy resin. One kind or two or more kinds of materials of the insulating materials can be used in combination. Among the insulating materials, it is particularly preferable to use various ceramics.

Although the package 110 has been described as above, a configuration of the package 110 is not particularly limited and an arbitrary configuration is available as long as the package 110 can exhibit its function.

The support substrate 120 is sandwiched between the base 111 and the housing 112 and is disposed so as to be drawn out from the inside space S1 to the outside of the package 110. The support substrate 120 supports the circuit element 130 and the pressure sensor 1 and electrically connects the circuit element 130 and the pressure sensor 1. As illustrated in FIG. 27, the support substrate 120 includes a base member 121 having flexibility and a plurality of wirings 129 disposed on the base member 121.

The base member 121 includes a frame shaped base portion 122 having an opening 122a, and a strip body 123 having a strip shape and extending from the base portion 122. Then, at the outer edge portion of the base portion 122, the strip body 123 is sandwiched between the base 111 and the housing 112 and extends to the outside of the package 110. As the base member 121, for example, a commonly used flexible printed substrate can be used. In the fourth embodiment, the base member 121 has flexibility, but all or a portion of the base member 121 may be rigid.

In plan view of the base member 121, the circuit element 130 and the pressure sensor 1 are positioned inside the opening 122a and are disposed by being aligned. The circuit element 130 and the pressure sensor 1 are suspended from the base member 121 via bonding wires BW, respectively, and are supported by the support substrate 120 in a state of being floated from the support substrate 120. The circuit element 130 and the pressure sensor 1 are electrically connected to each other through the bonding wires BW and wirings 129, respectively. As such, the circuit element 130 and the pressure sensor 1 are supported in a floating state with respect to the support substrate 120 such that stress is less likely to be transmitted from the support substrate 120 to the circuit element 130 and the pressure sensor 1 and pressure measurement accuracy of the pressure sensor 1 is improved.

The circuit element 130 includes a drive circuit for supplying a voltage to the bridge circuit 50, a temperature compensation circuit for performing temperature compensation on an output from the bridge circuit 50, a pressure measurement circuit for obtaining pressure received from an output from the temperature compensation circuit, and an output circuit for converting an output from the pressure measurement circuit into a predetermined output format (CMOS, LV-PECL, LVDS, and the like) and outputting the output.

The filling portion 140 is disposed in the internal space S1 so as to cover the circuit element 130 and the pressure sensor 1. With such a filling portion 140, the circuit element 130 and the pressure sensor 1 are protected (dustproof and waterproof), and external stress (for example, drop impact) acting on the pressure sensor 1 is less likely to be transmitted to the circuit element 130 and the pressure sensor 1.

The filling portion 140 can be formed of a liquid filler material or a gelled filler material, and in particular, the filling portion 140 is preferably made of a gelled filler in that excessive displacement of the circuit element 130 and the pressure sensor 1 can be suppressed. According to the filling portion 140, it is possible to effectively protect the circuit element 130 and the pressure sensor 1 from moisture and to efficiently transmit pressure to the pressure sensor 1. The filler forming the filling portion 140 is not particularly limited, and for example, silicone oil, fluorine oil, silicone gel, or the like can be used as the filler.

The pressure sensor module 100 has been described as above. The pressure sensor module 100 includes the pressure sensor 1 and the package 110 accommodating the pressure sensor 1. For that reason, the pressure sensor 1 can be protected by the package 110. It is possible to obtain the effect of the pressure sensor 1 described above and to exhibit high reliability.

The configuration of the pressure sensor module 100 is not limited to the configuration described above and a configuration in which for example, the filling portion 140 is omitted may be available. In the fourth embodiment, although the pressure sensor 1 and the circuit element 130 are supported in a state of being suspended on the support substrate 120 by the bonding wires BW, for example, the pressure sensor 1 and the circuit element 130 may be directly disposed on the support substrate 120. In the fourth embodiment, although the pressure sensor 1 and the circuit element 130 are disposed laterally by being aligned, for example, the pressure sensor 1 and the circuit element 130 may be disposed by being aligned in the height direction.

### Fifth Embodiment

Next, an electronic device according to a fifth embodiment of the invention will be described.

FIG. 28 is a perspective view illustrating an altimeter as an electronic device according to the fifth embodiment of the invention.

As illustrated in FIG. 28, an altimeter 200 as an electronic device can be worn on the wrist like a wrist watch. The pressure sensor 1 is mounted inside the altimeter 200 in which an altitude from sea level of the present location, atmospheric pressure of the present location, or the like can be displayed on a display unit 201. In the display unit 201, various pieces of information such as the current time, heart rate of a user, weather, and the like can be displayed.

The altimeter 200 which is an example of such an electronic device has the pressure sensor 1. For that reason, the altimeter 200 can obtain the effect of the pressure sensor 1 described above and can exhibit high reliability.

### Sixth Embodiment

Next, an electronic device according to a sixth embodiment of the invention will be described.

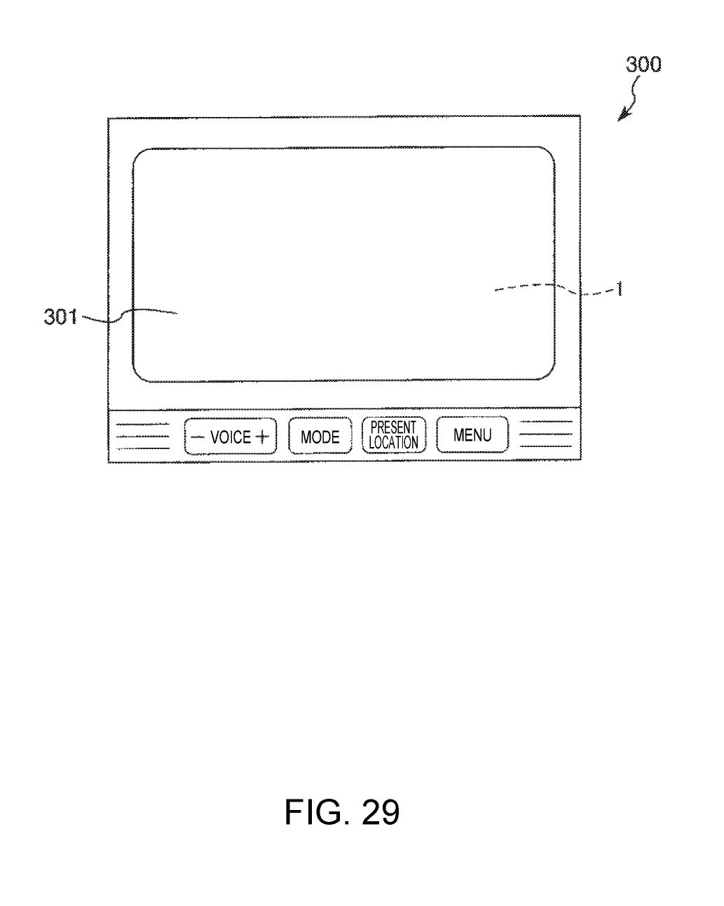

FIG. 29 is a front view illustrating a navigation system as an electronic device according to a sixth embodiment of the invention.

As illustrated in FIG. 29, a navigation system 300 as an electronic device includes a position information acquisition unit acquiring position information from map information (not illustrated) a global positioning system (GPS), an autonomous navigation unit configured with a gyro sensor, an acceleration sensor, and automobile speed data, a pressure sensor 1, and a display unit 301 for displaying predetermined position information or course information.

According to the navigation system 300, altitude information can be acquired in addition to acquired position information. For example, when the automobile is traveling on an elevated road for which a position that is substantially the same as a general road in terms of position information is illustrated, in the case of not having altitude information, the navigation system does not determine whether the automobile is traveling on the general road or on the elevated road, and provides general road information to the user as priority information. Accordingly, the pressure sensor 1 is mounted in the navigation system 300 and altitude information is acquired by the pressure sensor 1, so that altitude change due to entering the elevated road from the general road can be measured and navigation information can be provided to the user in the traveling state of the elevated road.

The navigation system 300 as an example of such an electronic device has the pressure sensor 1. For that reason, the navigation system 300 can obtain the effect of the pressure sensor 1 described above and can exhibit high reliability.

The electronic device according to the invention is not limited to the altimeter and the navigation system as described above, but may be applied to a personal computer, a digital still camera, a mobile phone, a smart phone, a tablet terminal, a watch (including smart watch), a drone, a medical instrument (for example, electronic clinical thermometer, blood pressure monitor, blood glucose meter, electrocardiogram measuring device, ultrasonic diagnostic device, electronic endoscope), various measuring instruments, instruments (for example, instruments of an automobile, aircraft, ship), a flight simulator, and the like.

### Seventh Embodiment

Next, a vehicle according to a seventh embodiment of the invention will be described.

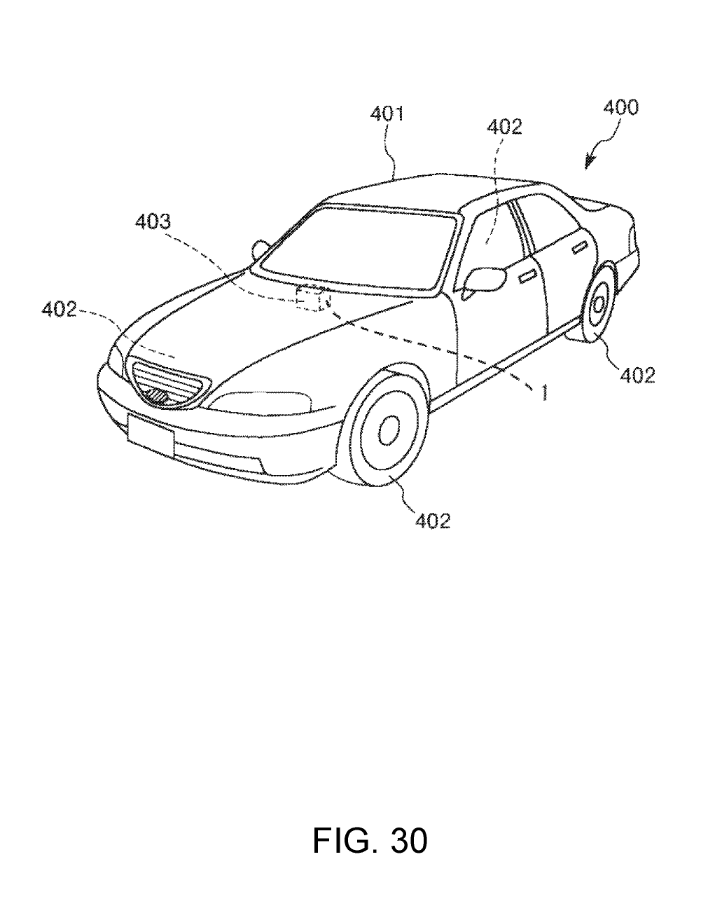

FIG. 30 is a perspective view illustrating an automobile as a vehicle according to a seventh embodiment of the invention.

As illustrated in FIG. 30, an automobile 400 as a vehicle has an automobile body 401 and four wheels 402 (tires), and is configured to rotate the wheels 402 by a power source (engine) (not illustrated) provided in the automobile body 401. The automobile 400 has an electronic control unit (ECU) 403 mounted on the automobile body 401, and a pressure sensor 1 is built in the electronic control unit 403. In the electronic control unit 403, the pressure sensor 1 measures acceleration, inclination, and the like of the automobile body 401 so that a moving state, a posture, and the like can be grasped and the wheels 402 and the like can be accurately controlled. With this, the automobile 400 can safely and stably move. The pressure sensor 1 may be mounted in a navigation system or the like provided in the automobile 400.

The automobile 400 as an example of such a vehicle has the pressure sensor 1. For that reason, the automobile 400 can obtain the effect of the pressure sensor 1 described above and can exhibit high reliability.

Although the pressure sensor, the manufacturing method of the pressure sensor, the pressure sensor module, the electronic device, and the vehicle according to the invention have been described based on the respective embodiments illustrated in the drawings, the invention is not limited thereto. The configuration of each unit can be replaced with an arbitrary configuration having the same function. Other arbitrary components and processes may be added. Also, respective embodiments may be appropriately combined.

The entire disclosure of Japanese Patent Application No. 2017-063331, filed Mar. 28, 2017 is expressly incorporated by reference herein.

What is claimed is:

1. A pressure sensor comprising:
a substrate having a diaphragm bent and deformed by pressure reception;
a side wall portion disposed on one surface side of the substrate and surrounding the diaphragm in plan view of the substrate;
a sealing layer disposed to face the diaphragm with space interposed between the sealing layer and the diaphragm and sealing the space; and
a frame shaped metal layer positioned between the side wall portion and the sealing layer,
wherein the sealing layer includes a first sealing layer having a through-hole facing the space, and
a second sealing layer positioned on a side opposite to the space with respect to the first sealing layer and sealing the through-hole, and
an inner peripheral end of the metal layer is positioned between the through-hole and an outer edge of the diaphragm in plan view of the substrate.

2. The pressure sensor according to claim 1,
wherein the through-hole overlaps with a central portion of the diaphragm in plan view of the substrate.

3. The pressure sensor according to claim 1,
wherein the metal layer includes a base portion having a portion positioned between the side wall portion and the sealing layer and a connection portion positioned between the base portion and the substrate and connected to the base portion.

4. The pressure sensor according to claim 3,
wherein the connection portion is embedded in the side wall portion.

5. The pressure sensor according to claim 1,
wherein the metal layer contains aluminum.

6. The pressure sensor according to claim 1,
wherein the sealing layer includes a third sealing layer positioned on a side opposite to the space with respect to the second sealing layer.

7. A pressure sensor module, comprising:
the pressure sensor according to claim 1; and
a package accommodating the pressure sensor.

8. An electronic device, comprising:
the pressure sensor according to claim 1.

9. A vehicle, comprising:
the pressure sensor according to claim 1.
